(19) United States
(12) Patent Application Publication
(10) Pub. No.: US 2026/0304943 A1
(43) Pub. Date: Oct. 1, 2026

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Ta-Chun LIN, Hsinchu (TW); Ming-Heng TSAI, Taipei (TW); Hong-Chih CHEN, Changhua County (TW); Jhon-Jhy LIAW, Zhudong Township (TW)

(73) Assignee: Taiwan Semiconductor Manufacturing Company, Ltd., Hsinchu (TW)

(21) Appl. No.: 19/093,740

(22) Filed: Mar. 28, 2025

(51) Int. Cl. H10D 84/85; H10D 30/00; H10D 30/01; H10D 30/43; H10D 62/10; H10D 62/13; H10D 62/60; H10D 64/23; H10D 84/01

(52) U.S. Cl. CPC H10D 84/851; H10D 30/014; H10D 30/0191; H10D 30/43; H10D 30/503; H10D 62/121; H10D 62/124; H10D 62/151; H10D 62/60; H10D 64/254; H10D 64/256; H10D 84/017; H10D 84/0186; H10D 84/856

(57) ABSTRACT

A semiconductor structure is provided. The semiconductor structure includes first nanostructures vertically stacked over each other, a first source/drain feature adjoining the first nanostructures, a first contact etching stop layer covering the first source/drain feature, a first interlayer dielectric layer on the first contact etching stop layer, and a first contact structure through the first interlayer dielectric layer, the first contact etching stop layer, and the first source/drain feature. The first contact structure includes a first portion through the first dielectric layer and a second portion through the first source/drain feature, a first sidewall of the first portion is connected to a second sidewall of the second portion through a connecting wall, and the second sidewall is indented from the first sidewall by a distance.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with conventional complementary metal-oxide-semiconductor (CMOS) processes, and their structure allows them to be aggressively scaled-down while maintaining gate control and mitigating SCEs. In conventional processes, GAA devices provide a channel in a silicon nanowire. However, integration of fabrication of the GAA features around the nanowire can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIG. 2 is a layout of a semiconductor structure, in accordance with some embodiments.

FIGS. 3A-1, 3B-1, 3C-1, 3D-1, 3E-1, 3F-1, 3G-1, 3H-1, 3I-1, 3J-1, 3K-1, 3L-1, 3M-1 and 3N-1 are cross-sectional views of the semiconductor structure at various intermediate stages corresponding to line X1-X1 of FIG. 2, in accordance with some embodiments of the disclosure.

FIGS. 3A-2, 3B-2, 3C-2, 3D-2, 3E-2, 3F-2, 3G-2, 3H-2, 3I-2, 3J-2, 3K-2, 3L-2, 3M-2 and 3N-2 are cross-sectional views of the semiconductor structure at various intermediate stages corresponding to line Y1-Y1 of FIG. 2, in accordance with some embodiments of the disclosure.

FIGS. 3J-3 and 3J-4 are enlarged views of FIGS. 3J-1 and 3J-2, in accordance with some embodiments of the disclosure.

FIGS. 3J-5 and 3J-6 are modifications of the semiconductor structure of FIGS. 3J-3 and 3J-4, in accordance with some embodiments of the disclosure.

FIGS. 3N-3 and 3N-4 are enlarged views of FIGS. 3N-1 and 3N-2, in accordance with some embodiments of the disclosure.

FIGS. 3N-5 and 3N-6 are modifications of the semiconductor structure of FIGS. 3N-3 and 3N-4, in accordance with some embodiments of the disclosure.

FIGS. 4-1 and 4-2 are cross-sectional views of the semiconductor structure corresponding to lines X1-X1 and Y1-Y1 of FIG. 2, in accordance with some embodiments of the disclosure.

FIGS. 5A-1, 5B-1, 5C-1, 5D-1, 5E-1 and 5F-1 are cross-sectional views of the semiconductor structure at an intermediate stage corresponding to line X1-X1 of FIG. 2, in accordance with some embodiments of the disclosure.

FIGS. 5A-2, 5B-2, 5C-2, 5D-2, 5E-2 and 5F-2 cross-sectional views of the semiconductor structure at an intermediate stage corresponding to line Y1-Y1 of FIG. 2, in accordance with some embodiments of the disclosure.

FIGS. 6A-1 and 6B-1 are cross-sectional views of the semiconductor structure at an intermediate stage corresponding to line X1-X1 of FIG. 2, in accordance with some embodiments of the disclosure.

FIGS. 6A-2 and 6B-2 cross-sectional views of the semiconductor structure at an intermediate stage corresponding to line Y1-Y1 of FIG. 2, in accordance with some embodiments of the disclosure.

FIGS. 7-1 and 7-2 are cross-sectional views of the semiconductor structure corresponding to lines X1-X1 and Y1-Y1 of FIG. 2, in accordance with some embodiments of the disclosure.

FIGS. 8A-1 and 8B-1 are cross-sectional views of the semiconductor structure at an intermediate stage corresponding to line X1-X1 of FIG. 2, in accordance with some embodiments of the disclosure.

FIGS. 8A-2 and 8B-2 cross-sectional views of the semiconductor structure at an intermediate stage corresponding to line Y1-Y1 of FIG. 2, in accordance with some embodiments of the disclosure.

FIGS. 9-1 and 9-2 are cross-sectional views of the semiconductor structure corresponding to lines X1-X1 and Y1-Y1 of FIG. 2, in accordance with some embodiments of the disclosure.

FIG. 9-3 is an enlarged view of FIG. 9-1, in accordance with some embodiments of the disclosure.

FIGS. 10A-1, 10B-1 and 10C-1 are cross-sectional views of the semiconductor structure at an intermediate stage corresponding to line X1-X1 of FIG. 2, in accordance with some embodiments of the disclosure.

FIGS. 10A-2, 10B-2 and 10C-2 cross-sectional views of the semiconductor structure at an intermediate stage corresponding to line Y1-Y1 of FIG. 2, in accordance with some embodiments of the disclosure.

FIGS. 11A-1, 11B-1 and 11C-1 are cross-sectional views of the semiconductor structure at an intermediate stage corresponding to line X1-X1 of FIG. 2, in accordance with some embodiments of the disclosure.

FIGS. 11A-2, 11B-2 and 11C-2 cross-sectional views of the semiconductor structure at an intermediate stage corresponding to line Y1-Y1 of FIG. 2, in accordance with some embodiments of the disclosure.

FIGS. 12A-1 and 12B-1 are cross-sectional views of the semiconductor structure at an intermediate stage corresponding to line X1-X1 of FIG. 2, in accordance with some embodiments of the disclosure.

FIGS. 12A-2 and 12B-2 cross-sectional views of the semiconductor structure at an intermediate stage corresponding to line Y1-Y1 of FIG. 2, in accordance with some embodiments of the disclosure.

FIGS. 13-1 and 13-2 are modifications of the semiconductor structure of FIGS. 3N-1 and 3N-2, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of a semiconductor structure are provided. The aspect of the present disclosure is directed to forming contact structures of a semiconductor structure. Contact openings are formed using two separate etching processes which are respectively performed before and after the formation of contact liners. As a result, the contact structure may extend deep into source/drain features while preventing the contact structure from coming into contact with barrier layers of source/drain features, or reduce the contact area between the contact structure and the barrier layers. In addition, the risk of leakage between the contact structure and the gate stack may be reduced. Therefore, the performance and/or the reliability of the resulting semiconductor devices may be enhanced, e.g., higher DC performance and/or lower leakage.

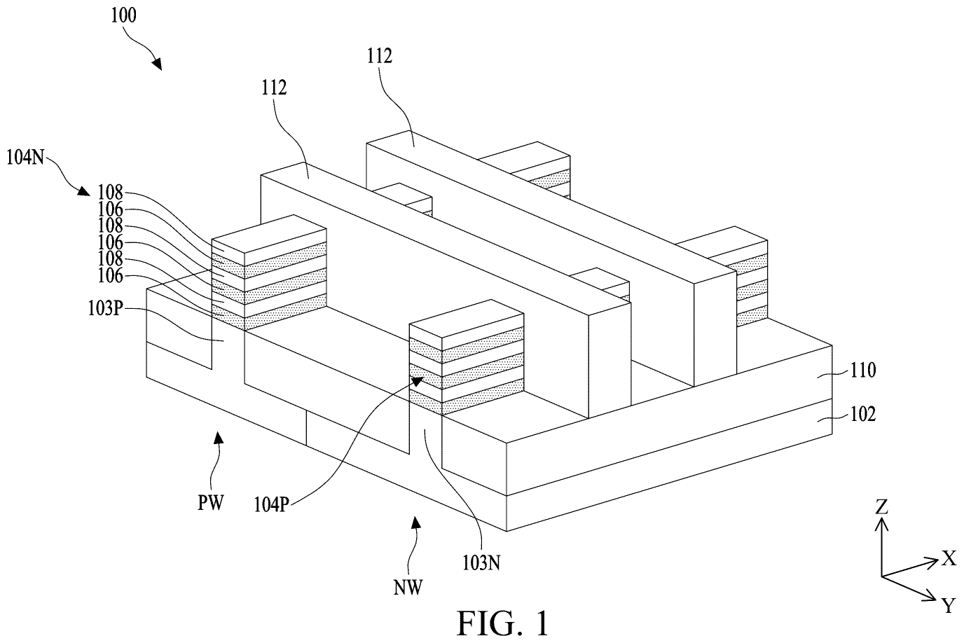

FIG. 1 is a perspective view of a semiconductor structure 100, in accordance with some embodiments of the disclosure. The semiconductor structure 100 includes a substrate 102 and fin structures 104 (including 104N and 104P) over the substrate 102, as shown in FIG. 1, in accordance with some embodiments. The substrate 102 includes a p-type well PW and an n-type well NW immediately adjacent to the p-type well PW, in accordance with some embodiments. The fin structure 104N is formed in the p-type well PW of the substrate 102, and the fin structure 104P is formed in the n-type well NW of the substrate 102, in accordance with some embodiments. The fin structures 104N and 104P are the active regions of the semiconductor structure 100, in accordance with some embodiments.

For a better understanding of the semiconductor structure 100, the X-Y-Z coordinate reference is provided in the figures of the present disclosure. The X-axis and the Y-axis are generally orientated along the lateral (or horizontal) directions that are parallel to the main surface of the substrate 102. The Y-axis is transverse (e.g., substantially perpendicular) to the X-axis. The Z-axis is generally oriented along the vertical direction. The vertical direction is perpendicular to the main surface of the substrate 102 (or the X-Y plane).

The fin structure 104N includes a lower fin element 103P formed from the p-type well PW, and the fin structure 104P includes a lower fin element 103N formed from the n-type well NW, in accordance with some embodiments. The lower fin elements 103P and 103N are surrounded by an isolation structure 110, in accordance with some embodiments. Each of the fin structures 104N and 104P further includes an upper fin element formed from an epitaxial stack including alternating first semiconductor layers 106 and second semiconductor layer 108, in accordance with some embodiments. The second semiconductor layers 108 will form nanostructures (e.g., nanowires or nanosheets) and serve as the channel for the resulting semiconductor devices, in accordance with some embodiments.

The fin structures 104N and 104P extend in the X direction, in accordance with some embodiments. That is, the fin structures 104N and 104P have longitudinal axes parallel to the X direction, in accordance with some embodiments. The X direction may also be referred to as the channel-extending direction. The current of the resulting semiconductor device (i.e., nanostructure transistor) flows in the X direction through the channel. Each of the fin structures 104 is defined as several channel regions and several source/drain regions, where the channel regions and the source/drain regions are alternately arranged, in accordance with some embodiments. It is noted that in the present disclosure, source/drain region(s) or source/drain feature(s) may refer to a source or a drain, individually or collectively dependent upon the context.

Gate structures 112 are formed with longitudinal axes parallel to the Y direction and extending across and/or surrounding the channel regions of the fin structures 104N and 104P, in accordance with some embodiments. The source/drain regions of the fin structures 104N and 104P are exposed from the gate structures 112, in accordance with some embodiments. The Y direction may also be referred to as a gate-routing direction.

Although two fin structures 104 are illustrated in FIG. 1, the semiconductor structure 100 may include more than two fin structures 104. In addition, FIG. 1 shows two gate structures 112 (or channel regions) for illustrative purposes and is not intended to be limiting. The number of fin structures and the gate structures may be dependent on design demand of an integrated circuit and/or performance consideration of semiconductor devices.

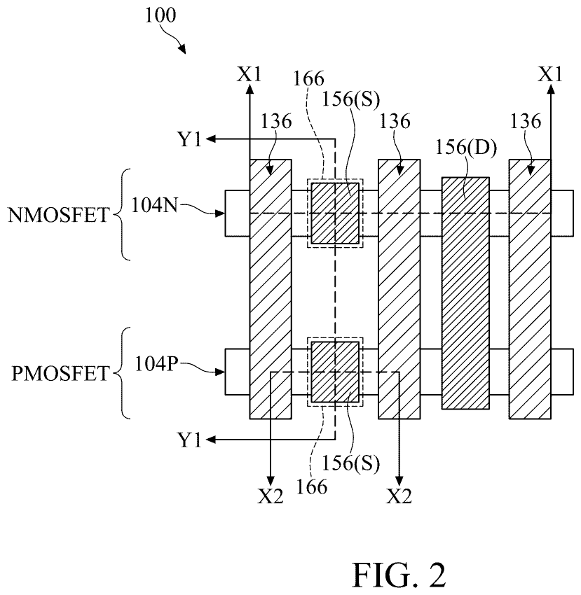

FIG. 2 illustrates a layout of a semiconductor structure 100 with a backside power rail architecture, in accordance with some embodiments. The semiconductor structure 100 is or includes nanostructure devices (e.g., GAA FETs), in accordance with some embodiments. In some embodiments, the semiconductor structure 100 includes active regions 104N and 104P over a substrate (as shown in FIG. 1), final gate stacks 136 across the active regions 104N and 104P, frontside contact structures 156 (including 156(S) and 156(D)), and backside contact structures 166.

The active region 104N is located in the p-type well (as shown in FIG. 1), and the active region 104P is located in the n-type well (as shown in FIG. 1), in accordance with some embodiments. Each of the active regions 104N and 104P includes a lower fin element (103N or 103P as shown in FIG. 1) longitudinally oriented along the X direction and nanostructures (not shown in FIG. 2) formed over the lower elements, in accordance with some embodiments.

The final gate stacks 136 are longitudinally oriented along the Y direction and across the lower fin elements, and wrap around the nanostructures of the active regions 104N and 104P and the nanostructures of the active regions 104N and 104P, in accordance with some embodiments. The final gate stacks 136 are combined with the nanostructures of the active regions 104N and 104P to form nanostructure transistors, in accordance with some embodiments. The nanostructure transistors are formed at the cross points between the active regions 104N and 104P and the final gate stacks 136, in accordance with some embodiments. The nanostructure transistors which are formed on the active region 104N (in the p-type well) are n-channel nanostructure transistors NMOSFET, and the nanostructure transistors which are formed on the active region 104P (in the n-type well) are p-channel nanostructure transistors PMOSFET, in accordance with some embodiments.

The frontside contact structures 156 are formed on the source/drain regions of the active regions 104N and 104P, and electrically connected to the source or drain terminals of the nanostructure transistors, in accordance with some embodiments. The frontside contact structures 156(S) are electrically connected to frontside power supply lines (not shown) and may also serve as Vdd/Vss nodes of the nanostructure transistors, in accordance with some embodiments. The contact structures 156(D) are electrically connected to signal lines (not shown) and may also serve as non-Vdd/Vss nodes of the nanostructure transistors.

Backside contact structures 166 are formed under the source/drain regions of the active regions 104N and 104P, in accordance with some embodiments. The contact structures 166 are electrically connected to the source terminals of the nanostructure transistors, in accordance with some embodiments. The backside contact structures 166 are electrically connected to backside power supply lines (not shown) and may also serve as Vdd/Vss nodes of the nanostructure transistors, in accordance with some embodiments. In some embodiments, the power rails are disposed on the dual sides of the semiconductor structure 100, which may reduce the total resistance of the metal layer. In some other embodiments, the frontside power rails are omitted, thereby relaxing the metal routing density.

As the scale of the semiconductor devices continues to shrink, the scaling of metal layers in BEOL has been touched by the limitation on both resistance and capacitance due to increasingly smaller line width and line space. As a result, the performance improvement (e.g., increase in speed) of semiconductor devices (e.g., logic circuits) cannot rely solely on the device boosting, but also needs to concern about the RC delay of the metal conductors (e.g., metal lines) as well as IR voltage drop of the power supply (e.g., Vdd and Vss truly voltage position during operation for logic circuit). The backside power rail can provide a backend metal routing for the semiconductor devices on the backside of the substrate, thereby reducing the overall resistance (e.g., contact resistance and/or sheet resistance) of the BEOL metal layers, and/or reducing the complexity of the metal routing on the frontside of the substrate. Therefore, the backside power rail architecture may facilitate the continued scaling of semiconductor devices.

FIG. 2 further illustrates reference cross-sections that are used in later figures. Cross-section X1-X1 is in a plane parallel to the longitudinal axis (X direction) of the active region 104N and through the active region 104N, cross-section X2-X2 is in a plane parallel to the longitudinal axis (X direction) of the active region 104P and through the active region 104N, and cross-section Y1-Y1 is in a plane parallel to the longitudinal axis (Y direction) of the final gate stack 136 and across two Vdd/Vss nodes of the nanostructure transistors NMOSFET and PMOSFET, in accordance with some embodiments.

FIGS. 3A-1 through 3N-2 are cross-sectional views illustrating the formation of the semiconductor structure 100 of FIG. 2 at various intermediate stages, in accordance with some embodiments of the disclosure. The figures ending with “−1” correspond to line X1-X1 shown in FIG. 2. The figures ending with “−2” correspond to line Y1-Y1 shown in FIG. 2.

FIGS. 3A-1 and 3A-2 illustrate the semiconductor structure 100 after the formation of active regions 104N and 104P, an isolation structure 110, dummy gate structures 112 and spacer layers 118, in accordance with some embodiments.

A substrate 102 is provided, as shown in FIGS. 3A-1 and 3A-2, in accordance with some embodiments. The substrate 102 may be a portion of a semiconductor wafer, a semiconductor chip (or die), and the like. In some embodiments, the substrate 102 is a silicon substrate. The frontside surface of the substrate 102 (the frontside of the semiconductor structure 100) faces upward, in accordance with some embodiments. In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

N-type dopants (such as phosphorus or arsenic) may be implanted into the substrate 102, thereby forming an n-type well (not shown), in accordance with some embodiments. P-type dopants (such as boron or BF₂) may be implanted into the substrate 102, thereby forming a p-type well (not shown), in accordance with some embodiments. In some embodiments, the respective concentrations of the dopants in the wells are in a range from about 10¹⁶/cm⁻³ to about 10¹⁸/cm⁻³. In some embodiments, the ion implantation processes may be performed several times with different dosages and different energy intensities. In some embodiments, the ion implantation process may include an anti-punch through (APT) implant.

Active regions 104N and 104P are formed over the substrate 102, as shown in FIGS. 3A-1 and 3A-2, in accordance with some embodiments. The active region 104N is formed in the p-type well, and the active region 104P is formed in the n-type well, in accordance with some embodiments. In some embodiments, the active regions 104N and 104P extend in the X direction.

The formation of the active regions 104N and 104P includes forming an epitaxial stack over the substrate 102 using an epitaxial growth process, in accordance with some embodiments. The epitaxial stack includes alternating first semiconductor layers 106 and second semiconductor layers 108, in accordance with some embodiments. The epitaxial growth process may be molecular beam epitaxy (MBE), metal organic chemical vapor deposition (MOCVD), or vapor phase epitaxy (VPE), or another suitable technique.

In some embodiments, the first semiconductor layers 106 are made of a first semiconductor material and the second semiconductor layers 108 are made of a second semiconductor material. The first semiconductor material for the first semiconductor layers 106 has a different lattice constant than the second semiconductor material for the second semiconductor layers 108, in accordance with some embodiments. In some embodiments, the first semiconductor material and the second semiconductor material have different oxidation rates and/or etching selectivity. In some embodiments, the first semiconductor layers 106 are made of SiGe, where the percentage of germanium (Ge) in the SiGe is in a range from about 20 atomic % to about 50 atomic %, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{1-y}Ge_{y}, where y is less than about 0.4, and x>y.

The first semiconductor layers 106 are configured as sacrificial layers and will be removed to form gaps to accommodate gate materials, and the second semiconductor layers 108 will form nanostructures (e.g., nanowires or nanosheets) that laterally extend between source/drain features and serve as the channel for the resulting semiconductor devices (such as nanostructure transistors), in accordance with some embodiments.

The formation of the active regions 104N and 104P further includes patterning the epitaxial stack and the underlying p-type and n-type well using photolithography and etching processes, thereby forming trenches and the active regions 104N and 104P protruding from between trenches, in accordance with some embodiments. The portion of the p-type well protruding from between the trenches serves as a lower fin element 103P of the active region 104N, and the portion of the n-type well NW protruding from between the trenches serves as a lower fin element 103N of the active region 104P, in accordance with some embodiments. A remainder of the epitaxial stack (including the first semiconductor layers 106 and the second semiconductor layers 108) serves as the upper fin elements of the active regions 104N and 104P, in accordance with some embodiments. In some embodiments, the active regions 104N and 104P are the fin structures 104N and 104P as shown in FIG. 1.

In some embodiments, each of the first semiconductor layers 106 has a thickness in a range from about 6 nm to about 15 nm. In some embodiments, each of the second semiconductor layers 108 has a thickness in a range from about 4 nm to about 8 nm. The thickness of the second semiconductor layers 108 may be greater than, equal to, or less than the first semiconductor layers 106, depending on the amount of gate materials to be filled in spaces where the first semiconductor layers 106 are removed. Although three first semiconductor layers 106 and three second semiconductor layers 108 are shown in FIGS. 3A-1 and 3A-2, the number is not limited to three, and can be two or four, and is less than 10.

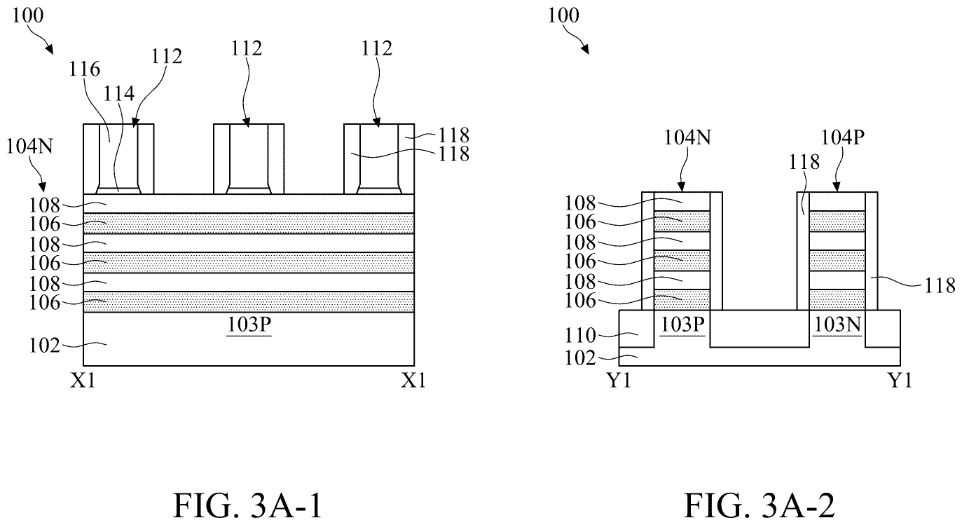

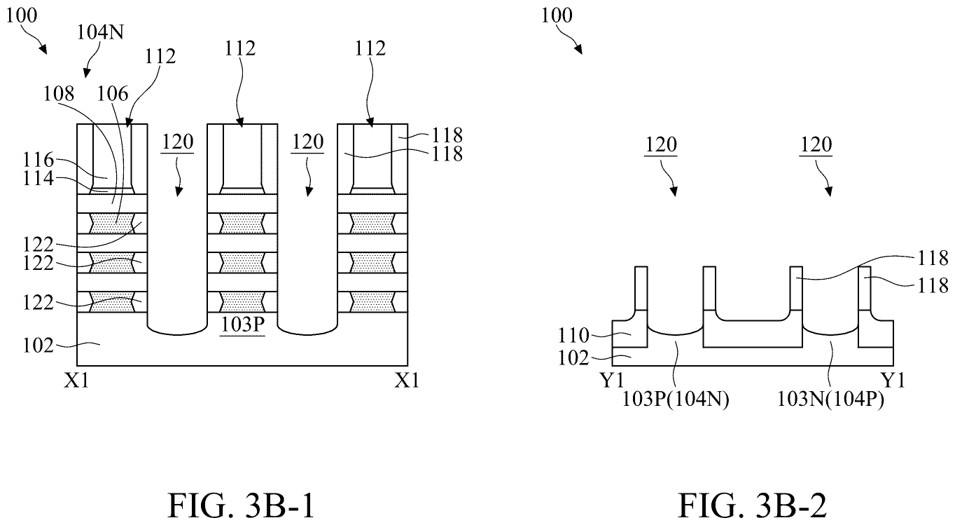

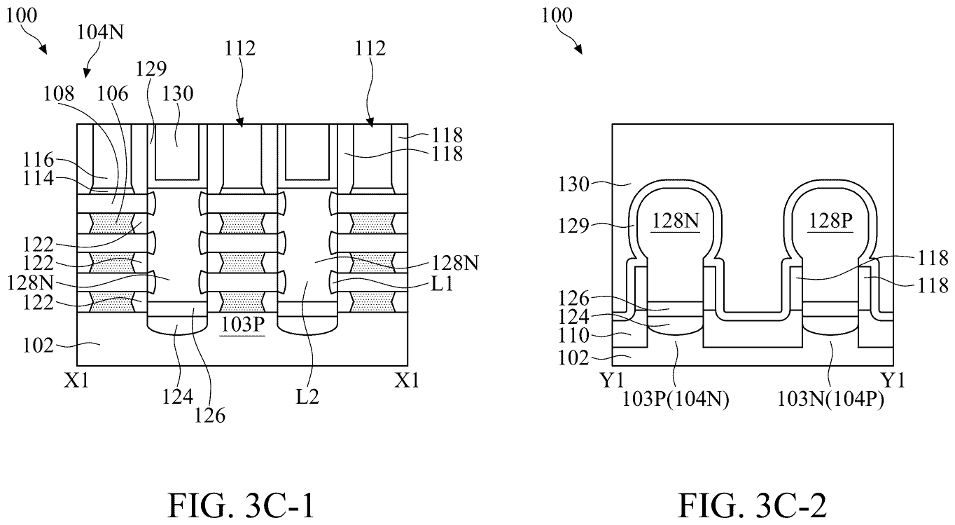

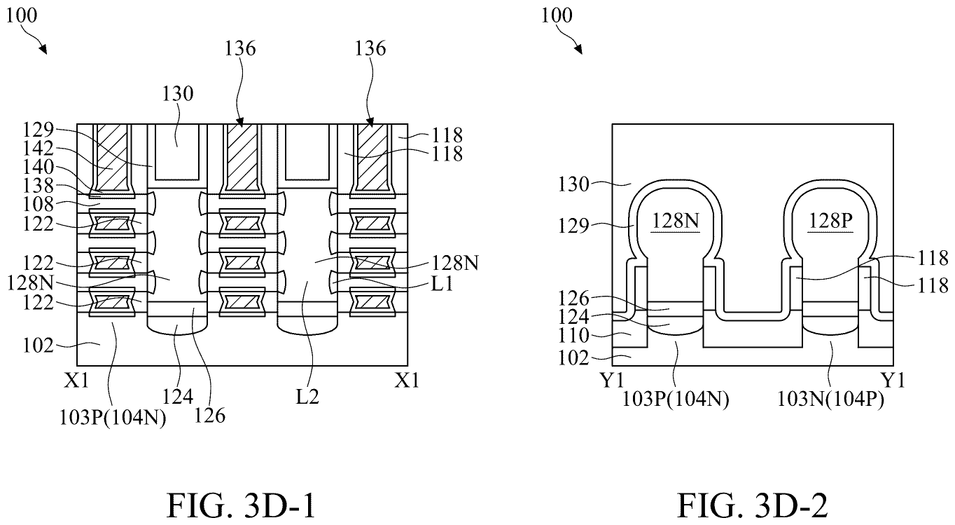

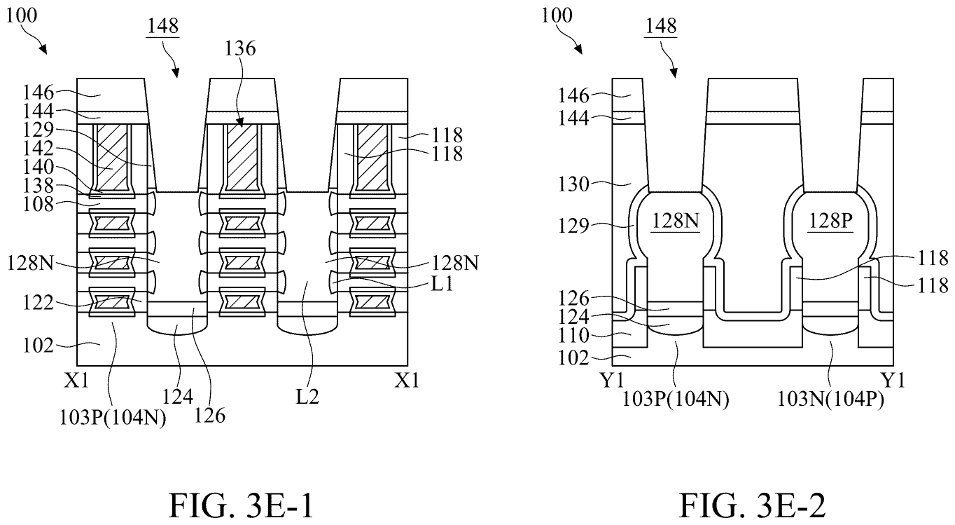

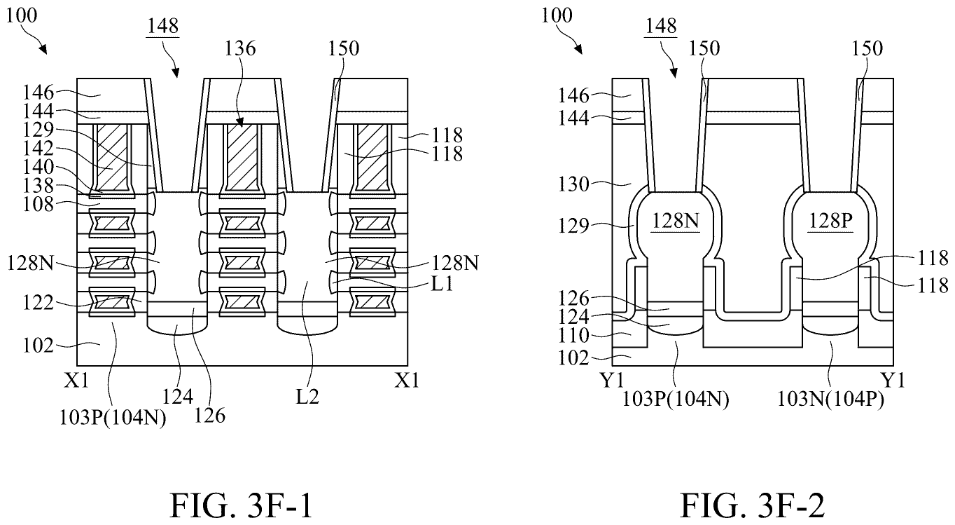

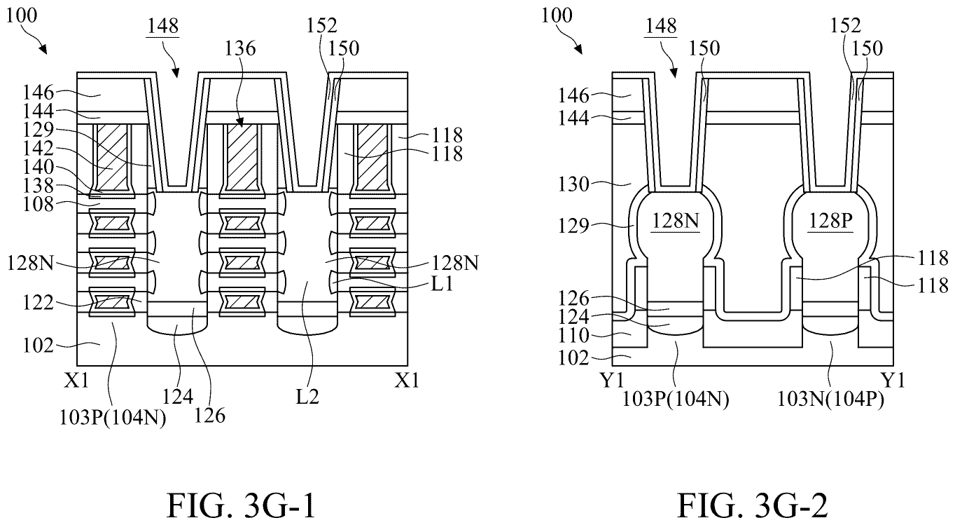

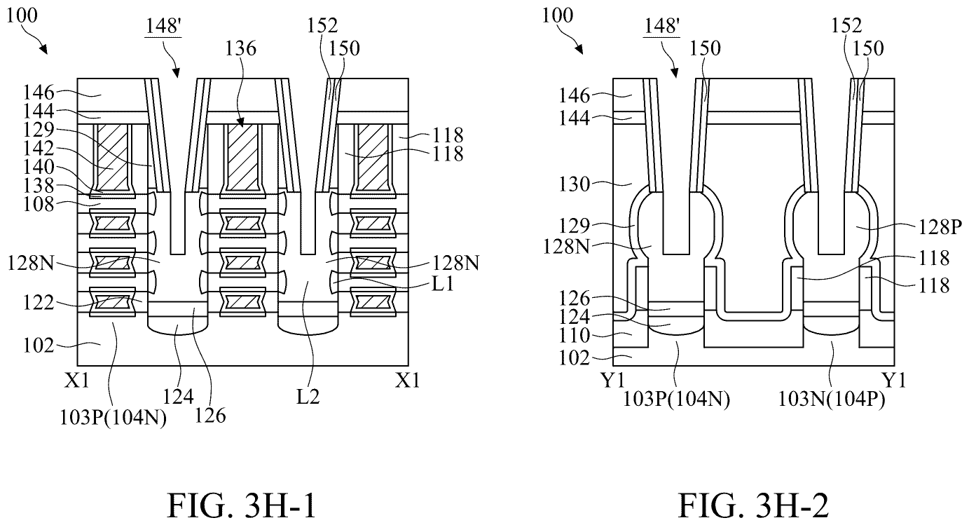

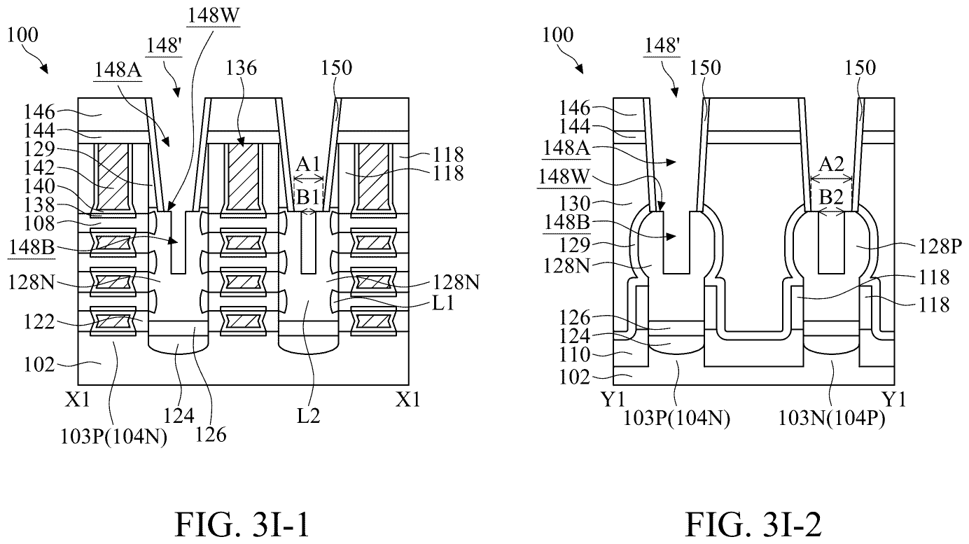

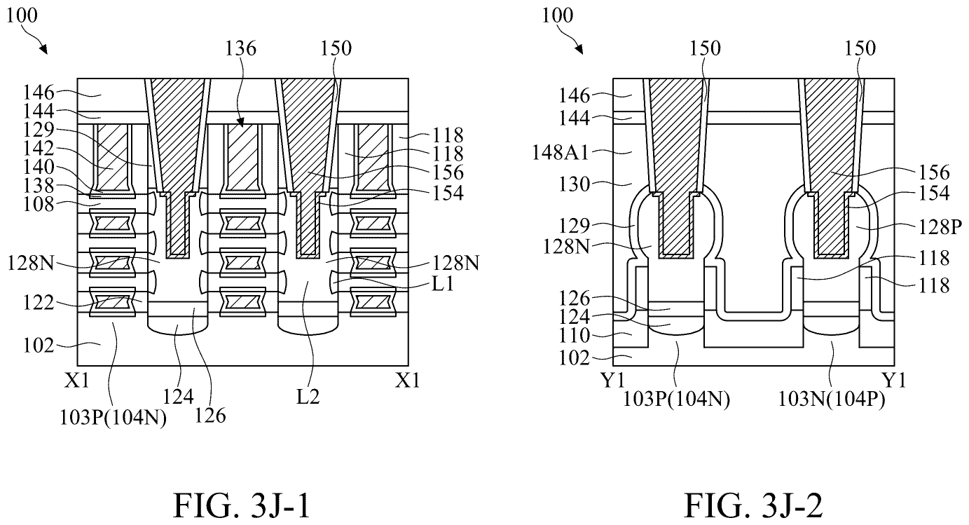

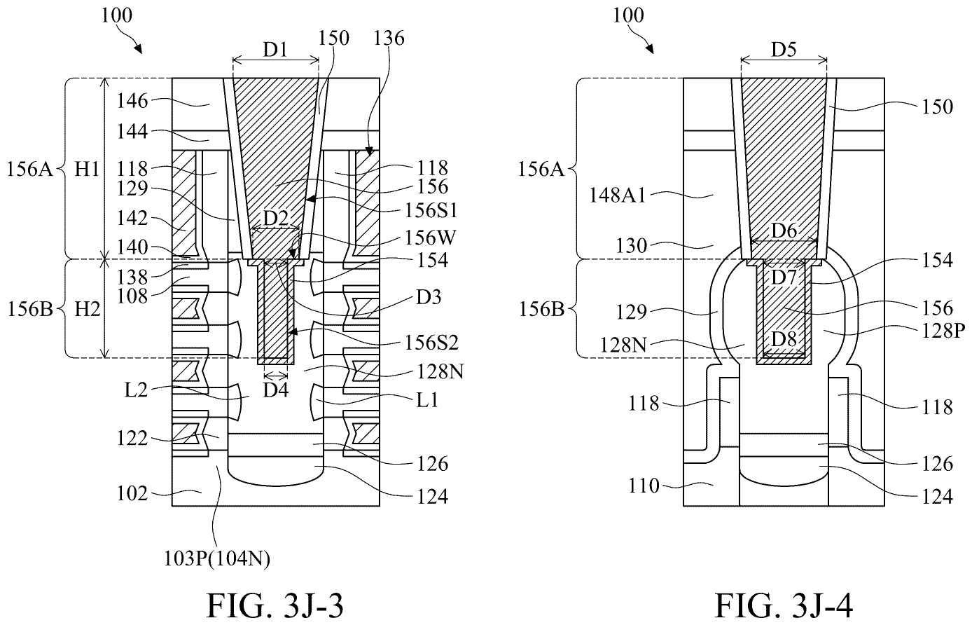

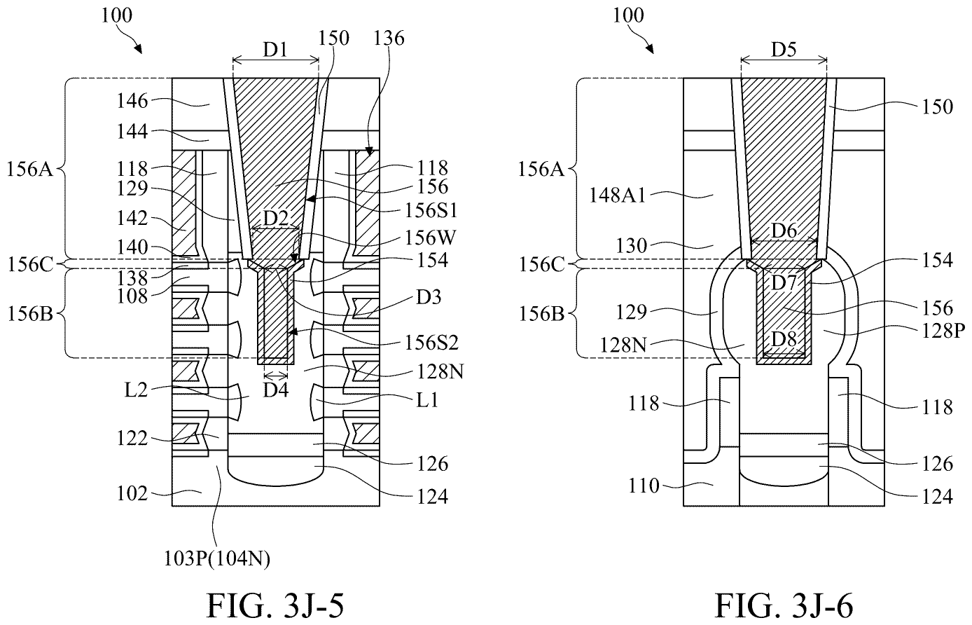

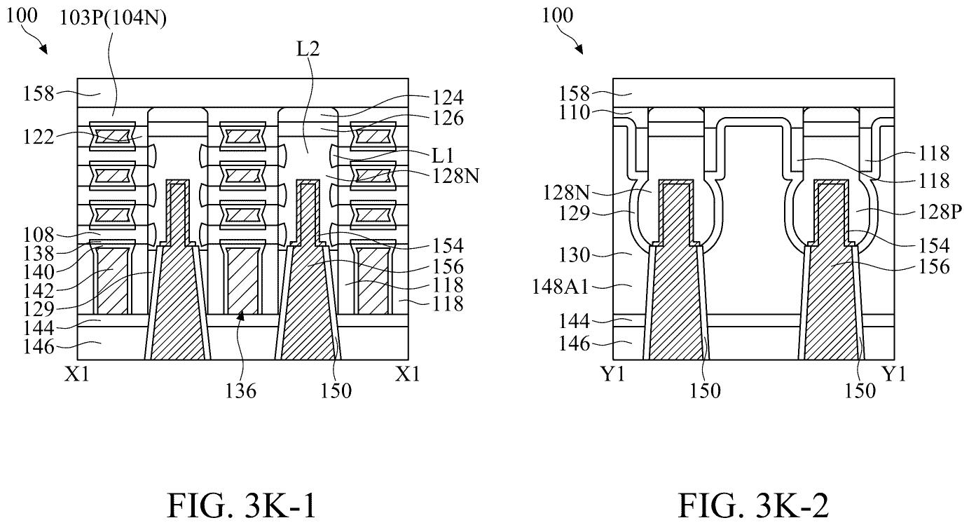

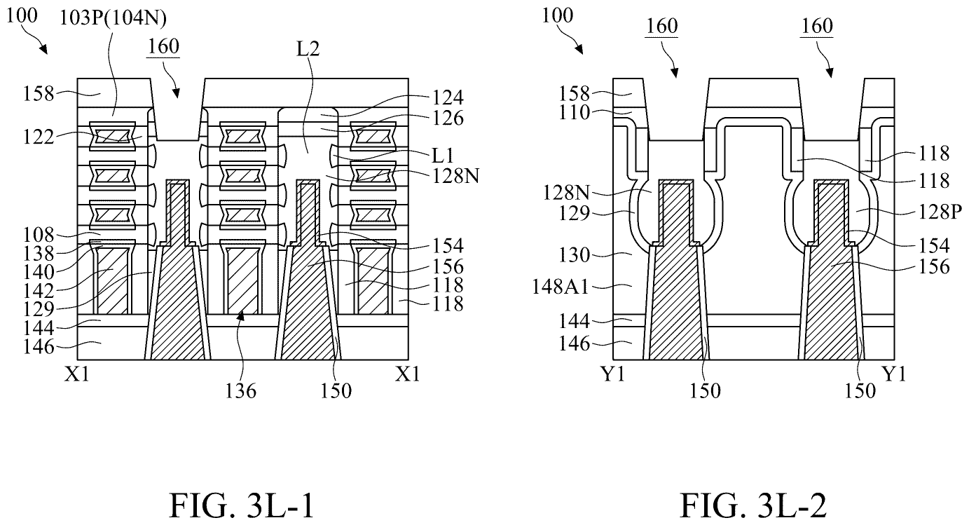

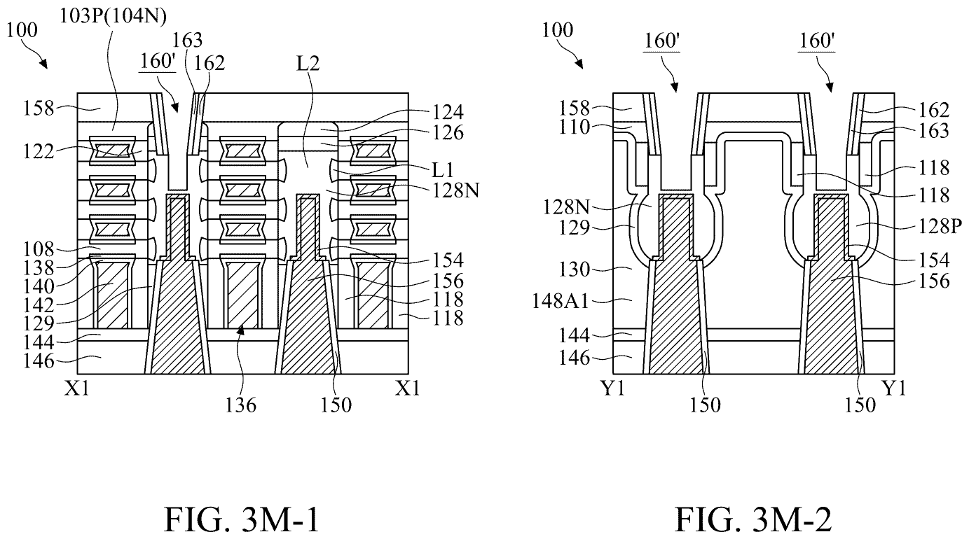

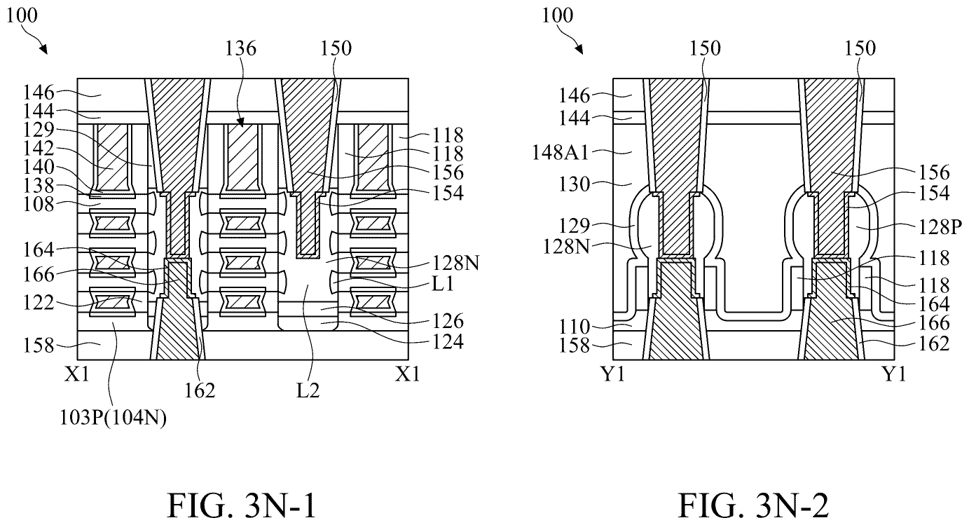

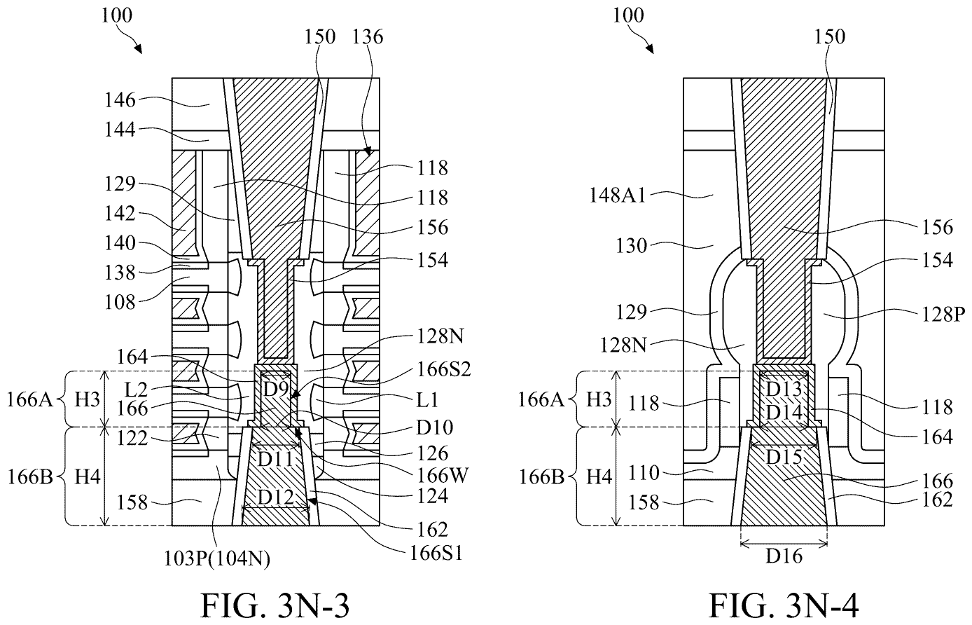

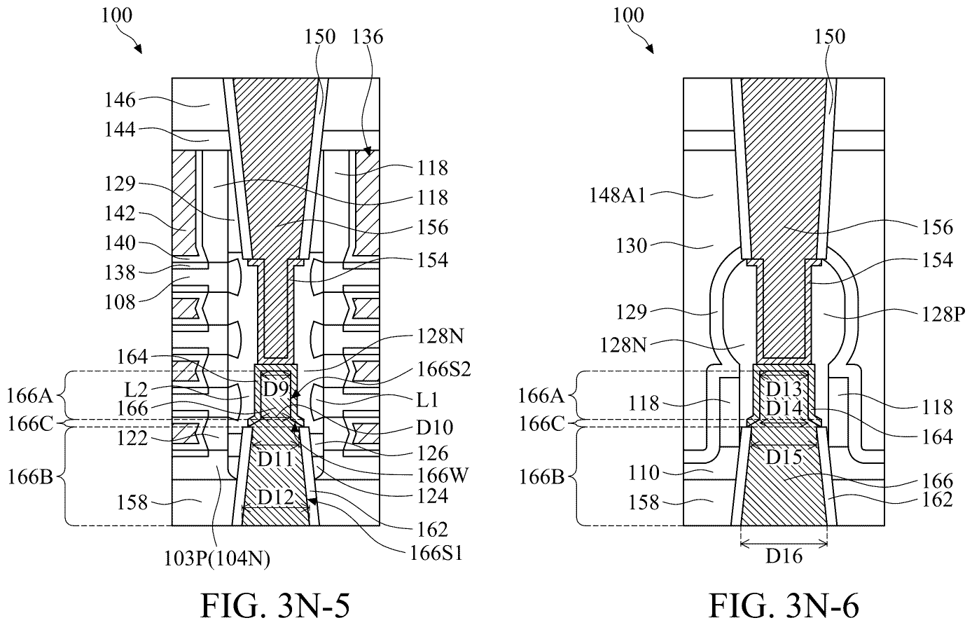

An isolation structure 110 is formed to surround the lower fin elements 103P and 103N of the active regions 104N and 104P, as shown in FIG. 3A-2, in accordance with some embodiments. The isolation structure 110 is configured to electrically isolate the active regions 104N and 104P from each other and is also referred to as shallow trench isolation (STI) feature, in accordance with some embodiments. The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process is performed on the insulating material to remove a portion of the insulating material above the active regions 104N and 104P, in accordance with some embodiments. The planarization may be chemical mechanical polishing (CMP), etching back process, or a combination thereof. The insulating material is then recessed using an etching process (such as dry plasma etching and/or wet chemical etching) until the upper fin elements of the active regions 104N and 104P are exposed, in accordance with some embodiments.

Dummy gate structures 112 are formed across the active regions 104N and 104P, as shown in FIG. 3A-1, in accordance with some embodiments. The dummy gate structures 112 are configured as sacrificial structures and will be replaced with the final gate stacks and the fin isolation structures, in accordance with some embodiments. In some embodiments, the dummy gate structures 112 extend in the Y direction. The dummy gate structures 112 surround the channel regions of the active regions 104N and 104P, in accordance with some embodiments. The dummy gate structures 112 may be similar to the gate structures 112 shown in FIG. 1.

Each of the dummy gate structures 112 includes a dummy gate dielectric layer 114 and a dummy gate electrode layer 116 over the dummy gate dielectric layer 114, in accordance with some embodiments. In some embodiments, the dummy gate dielectric layer 114 is conformally formed along the upper fin elements of the active regions 104. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HfTiO, HfAlO. In some embodiments, the dielectric material is deposited using ALD, CVD, thermal oxidation, physical vapor deposition (PVD), another suitable technique, or a combination thereof.

In some embodiments, the material for the dummy gate electrode layer 116 is deposited using CVD, ALD, another suitable technique, or a combination thereof. Once the material for the dummy gate electrode layer 116 is deposited, the material for the dummy gate electrode layer 116 is planarized, and the material for the dummy gate electrode layer 116 and the dielectric material are patterned into the dummy gate structures 112 using photolithography and etching processes.

Spacer layers 118 are formed along the opposite sidewalls of the dummy gate structures 112 and the opposite sidewalls of the active regions 104N and 104P, as shown in FIGS. 3A-1 and 3A-2, in accordance with some embodiments. In some embodiments, the spacer layers 118 are made of a dielectric material, such as silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material. In some embodiments, the formation of the spacer layers 118 includes globally and conformally dielectric material over the semiconductor structure 100A using ALD, CVD (such as LPCVD, PECVD or HDP-CVD or a combination thereof, followed by an anisotropic etching process, in accordance with some embodiments.

The vertical portions of the spacer layers 118 that are left remaining on the opposite sides of the dummy gate structures 112 may be referred to as gate spacer, and the vertical portions of the spacer layers 118 left on the opposite sides of the active regions 104N and 104P may be referred to as fin spacer. The gate spacer is used to offset the subsequently formed source/drain features and separate the source/drain features from the gate structure, in accordance with some embodiments. The fin spacer is used to constrain the lateral growth of subsequently formed source/drain features, in accordance with some embodiments.

FIGS. 3B-1 and 3B-2 illustrate the semiconductor structure 100 after the formation of source/drain recesses 120 and inner spacer layers 122, in accordance with some embodiments.

An etching process is performed to recess the source/drain regions of the active regions 104N and 104P, thereby forming source/drain recesses 120, as shown in FIGS. 3B-1 and 3B-2, in accordance with some embodiments. The etching process may be an anisotropic etching process such as dry plasma etching, an isotropic etching process such as dry chemical etching, remote plasma etching or wet chemical etching, or a combination thereof. The spacer layers 118 and the dummy gate structures 112 may serve as etch masks such that the source/drain recesses 120 are formed self-aligned on opposite sides of the dummy gate structures 112, in accordance with some embodiments. The source/drain recesses 120 extend a distance into the lower fin elements 103N and 103P, in accordance with some embodiments. In some embodiments, the isolation structure 110 is also recessed.

An etching process is performed to laterally recess, from the source/drain recesses 120, the first semiconductor layers 106 of the active regions 104N and 104P, thereby forming notches, and then inner spacer layers 122 are formed in the notches, as shown in FIG. 3B-1, in accordance with some embodiments. The inner spacer layers 122 are formed to abut the recessed side surfaces of the first semiconductor layers 106, in accordance with some embodiments. In some embodiments, the inner spacer layers 122 are located between adjacent second semiconductor layers 108 and between the bottommost second semiconductor layer 108 and the lower fin element 103N (or 103P). The inner spacer layers 122 may avoid the source/drain features and the gate stack from being in direct contact and are configured to reduce the parasitic capacitance between the gate stack and the source/drain features (i.e., Cgs and Cgd), in accordance with some embodiments.

In some embodiments, the inner spacer layers 122 are made of a dielectric material, such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), a multilayer thereof, or a combination thereof. In some embodiments, the inner spacer layers 122 are formed by depositing a dielectric material for the inner spacer layers 122 over the semiconductor structure 100 to overfill the notches, and then etching back the dielectric material to remove the dielectric material outside the notches. In some embodiments, the deposition process includes ALD, CVD (such as PECVD, LPCVD or HARP), another suitable technique, or a combination thereof. In some embodiments, the etching back process includes an anisotropic etching process such as dry plasma etching, an isotropic etching process such as dry chemical etching, remote plasma etching or wet chemical etching, or a combination thereof.

FIGS. 3C-1 and 3C-2 illustrate the semiconductor structure 100 after the formation of separation layers 124 and 126, source/drain features 128N and 128P (including 128N and 128P), a contact etching stop layer 129 and a first interlayer dielectric layer 130, in accordance with some embodiments.

First separation layers 124 are optionally grown on the lower fin elements 103N and 103P, as shown in FIGS. 3C-1 and 3C-2, in accordance with some embodiments. In some embodiments, the first separation layers 124 are made of an epitaxial semiconductor material such as silicon, silicon germanium or germanium, formed by MBE, MOCVD, or VPE, another suitable technique, or a combination thereof. In an embodiment, the first separation layers 124 are made of non-doped silicon.

Second separation layers 126 are optionally formed on the first separation layers 124, as shown in FIGS. 3C-1 and 3C-2, in accordance with some embodiments. In some embodiments, the second separation layers 126 are made of dielectric material such as silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN). In some embodiments, the second separation layers 126 are formed using a deposition process followed by and an etching-back process.

In some embodiments, the sidewalls of the bottommost second semiconductor layers 108 are uncovered by the second separation layers 126. The first separation layers 124 and the second separation layers 126 may be configured to reduce the total cell capacitance and/or the leakage caused by the bottom planar transistor formed from the lower fin elements, in accordance with some embodiments.

Source/drain features 128N and 128P are formed on the exposed sidewalls of the second semiconductor layers 108 using one or more epitaxial growth processes, as shown in FIGS. 3C-1 and 3C-2, in accordance with some embodiments. These epitaxial growth processes may be MBE, MOCVD, or VPE, another suitable technique, or a combination thereof. The source/drain features 128N and 128P are located on the second separation layers 126 in the source/drain recesses 120, in accordance with some embodiments. The source/drain features 128N and 128P are located on opposite sides of the dummy gate structures 112, in accordance with some embodiments. In some embodiments, the source/drain features 128N have a different electrically conductive type than the source/drain features 128P.

In some embodiments, the source/drain features 128N and the source/drain features 128P may be formed separately. For example, a patterned mask layer (such as a photoresist layer and/or a hard mask layer) may be formed to cover the semiconductor structure 100 over the n-type well, and then the source/drain features 128N are grown. Afterward, the patterned mask layer may be removed. Similarly, a patterned mask layer (such as a photoresist layer and/or a hard mask layer) is formed to cover the semiconductor structure 100 over the p-type well, and then the source/drain features 128P are grown. Afterward, the patterned mask layer may be removed. In some embodiments, the source/drain features 128N and 128P are in-situ doped during the epitaxial processes.

In some embodiments, the source/drain features 128N are doped with the n-type dopant during the epitaxial growth process. For example, the n-type dopant may be phosphorous (P) or arsenic (As). For example, the n-type source/drain features 128N may be the epitaxially grown silicon phosphorous (SiP), silicon carbon (SiC), silicon phosphorous carbon (SiPC), silicon phosphorous arsenic (SiPAs), silicon arsenic (SiAs), silicon (Si), or a combination thereof doped with phosphorous and/or arsenic.

In some embodiments, the source/drain features 128P are doped with the p-type dopant during the epitaxial growth process. For example, the p-type dopant may be boron (B) or BF₂. For example, the p-type source/drain features 128P may be the epitaxially grown silicon germanium (SiGe), silicon germanium carbon (SiGeC), germanium (Ge), silicon (P), or a combination thereof doped with boron (B).

In some embodiments, each of the source/drain features 128N and 128P may be multilayered structures, e.g., including epitaxial barrier layers L1 formed on the sidewalls of the second semiconductor layers 108, and an epitaxial bulk layer L2 then filling remaining portions of the source/drain recesses 120, as shown in FIG. 3C-1. In some embodiments, the epitaxial bulk layer L2 is separate from the second semiconductor layers 108 by the epitaxial barrier layers L1.

In some embodiments, the concentration of the dopant in the bulk layer L2 is higher than the concentration of the dopant in the barrier layers L1, e.g., by 1-2 orders. In some embodiments, the concentrations of the dopant (e.g., P) in the bulk layer L2 of the source/drain features 128N are in a range from about 2×10¹⁹ cm⁻³ to about 3×10²¹ cm⁻³. In some embodiments, the concentrations of the dopant (e.g., B) in the bulk layer L2 of the source/drain features 128P are in a range from about 1×10¹⁹ cm⁻³ to about 6×10²⁰ cm⁻³. In some embodiments, the n-type source/drain features 128N and the p-type source/drain features 128P are made of different epitaxial materials. For example, the n-type source/drain features 128N are made of SiP, and the p-type source/drain features 128P are made of SiGe.

In some embodiments, the thickness (the dimension in the X direction) and width (the dimension in the Y direction) of the n-type source/drain features 128N (or the p-type source/drain features 128P) are different. For example, the thickness (the dimension in the X direction) of the source/drain features 128N (or 128P) is greater than the width (the dimension in the Y direction) of the source/drain features 128N (or 128P).

A contact etching stop layer 129 is formed over the semiconductor structure 100 to cover the source/drain features 128N and 128P, as shown in FIGS. 3C-1 and 3C-2, in accordance with some embodiments. In some embodiments, the contact etching stop layer 129 is made of a dielectric material, such as silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material. In some embodiments, the contact etching stop layer 129 is globally and conformally deposited using ALD, CVD (such as LPCVD, PECVD, HDP-CVD and HARP), another suitable method, and/or a combination thereof.

A first interlayer dielectric layer 130 is formed over the contact etching stop layer 129, as shown in FIGS. 3C-1 and 3C-2, in accordance with some embodiments. The first interlayer dielectric layer 130 overfills the space between dummy gate structures 112, in accordance with some embodiments. In some embodiments, the first interlayer dielectric layer 130 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), or another suitable dielectric material. In some embodiments, the dielectric constant of the CESL is greater than the dielectric constant of the first interlayer dielectric layer 130. In some embodiments, the dielectric material for the first interlayer dielectric layer 130 is deposited using such as CVD (such as HDP-CVD, PECVD, HARP or FCVD), another suitable technique, or a combination thereof. The dielectric materials for the contact etching stop layer 129 and the first interlayer dielectric layer 130 above the top surface of the dummy gate electrode layer 116 are removed using such as CMP, in accordance with some embodiments.

The contact etching stop layer 129 is thinner than the first interlayer dielectric layer 130, in accordance with some embodiments. For example, the thickness of the portion of the contact etching stop layer 129 along the spacer layer 118 (extending along the X direction) and the thickness of the portion of the contact etching stop layer 129 along the upper surface of the source/drain features 128N and 129P (extending along the X direction) is less than the thickness of the first interlayer dielectric layer 130.

FIGS. 3D-1 and 3D-2 illustrate cross-sectional views of the semiconductor structure 100 after the formation of final gate stacks 136, in accordance with some embodiments.

One or more etching processes are performed to remove the dummy gate structures 112 to form gate trenches, and remove the first semiconductor layers 106 of the active regions 104N and 104P to form gaps, in accordance with some embodiments. In some embodiments, the gate trenches expose the channel regions of the active regions 104N and 104P. In some embodiments, the gate trenches further expose the sidewalls of the gate spacers facing the channel region. In some embodiments, the gaps expose the sidewalls of the inner spacer layers 122 facing the channel region. The one or more etching processes may include an anisotropic etching process such as dry plasma etching, an isotropic etching process such as dry chemical etching, remote plasma etching or wet chemical etching, or a combination thereof.

After the one or more etching processes, the four main surfaces of the second semiconductor layers 108 are exposed, in accordance with some embodiments. The exposed second semiconductor layers 108 form sets of nanostructures 108, in accordance with some embodiments. Each set includes three nanostructures 108 vertically stacked and spaced apart from one other, in accordance with some embodiments. As the term is used herein, “nanostructures” refers to the semiconductor layers with cylindrical shape, bar shaped and/or sheet shape. The nanostructures 108 function as channels of the resulting semiconductor devices (e.g., nanostructure transistors such as GAA transistors), in accordance with some embodiments.

Final gate stacks 136 are formed in the gate trenches and gaps, thereby wrapping around the nanostructures 108, as shown in FIG. 3D-1, in accordance with some embodiments. In some embodiments, the final gate stacks 136 extend in the Y direction. The final gate stacks 136 engage the channel region so that current can flow between the source/drain regions during operation.

In some embodiments, each of the final gate stacks 136 includes an interfacial layer 138, a gate dielectric layer 140 and a metal gate electrode layer 142, as shown in FIG. 3D-1, in accordance with some embodiments. The interfacial layer 138 is formed on the exposed surfaces of the nanostructures 108 and the exposed surfaces of the lower fin elements 103N and 103P, in accordance with some embodiments. The interfacial layer 138 wraps around the nanostructures 108, in accordance with some embodiments.

In some embodiments, the interfacial layer 138 is made of a chemically formed silicon oxide. In some embodiments, the interfacial layer 138 is nitrogen-doped silicon oxide. In some embodiments, the interfacial layer 138 is formed using one or more cleaning processes such as including ozone (O₃), ammonia hydroxide-hydrogen peroxide-water mixture, and/or hydrochloric acid-hydrogen peroxide-water mixture. Semiconductor material from the nanostructures 108 and the lower fin elements 103N and 103P is oxidized to form the interfacial layer 138, in accordance with some embodiments.

The gate dielectric layer 140 is formed conformally along the interfacial layer 138 to wrap around the nanostructures 108, in accordance with some embodiments. The gate dielectric layer 140 is further formed along the exposed sidewalls of the spacer layers 118 and the inner spacer layers 122 facing the channel region, in accordance with some embodiments. The gate dielectric layer 140 may be a high-k dielectric layer. In some embodiments, the high-k dielectric layer is dielectric material with a high dielectric constant (k value), for example, greater than 9, such as greater than 13. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba, Sr)TiO₃ (BST), Si₃N₄, oxynitrides (SiON), a combination thereof, or another suitable material. The high-k dielectric layer may be deposited using ALD, PVD, CVD, or another suitable technique.

The metal gate electrode layer 142 is formed over the gate dielectric layer 140 and overfills the remainder of the gate trench and the gaps, in accordance with some embodiments. In some embodiments, the metal gate electrode layer 142 is made of more than one conductive material, such as a metal, metal alloy, conductive metal oxide and/or metal nitride, another suitable conductive material, or a combination thereof. For example, the metal gate electrode layer 142 may be made of Ti, Ag, Al, TiAlN, TaC, TaCN, TaSiN, Mn, Zr, TiN, TaN, Ru, Mo, WN, Cu, W, Re, Ir, Co, Ni, Pt, another suitable conductive material, or multilayers thereof. The metal gate electrode layer 142 may be a multi-layer structure with various combinations of a diffusion barrier layer, work function layers with a selected work function to enhance the device performance for n-channel FETs or p-channel FETs, a capping layer to prevent oxidation of work function layers, a glue layer to adhere work function layers to the next layer, and a metal fill layer to reduce the total resistance of gate stacks, or another suitable layer.

A planarization process such as CMP may be performed on the semiconductor structure 100 to remove the materials of the gate dielectric layer 140 and the metal gate electrode layer 142 formed above the upper surface of the first interlayer dielectric layer 130, in accordance with some embodiments. The final gate stacks 136 that are wrapped around the nanostructures 108 combine with the neighboring source/drain features 128N or 128P to form nanostructure transistors. In some embodiments, the transistors formed on the nanostructures 108 in the p-type well are the n-channel nanostructure transistors (NMOSFET in FIG. 2), and the transistors formed on the nanostructures 108 in the n-type well are the p-channel nanostructure transistors (PMOSFET in FIG. 2).

FIGS. 3E-1 and 3E-2 illustrate the semiconductor structure 100 after the formation of an etching stop layer 144, a second interlayer dielectric layer 146 and contact openings 148, in accordance with some embodiments.

An etching stop layer 144 is formed over the semiconductor structure 100, as shown in FIGS. 3E-1 and 3E-2, in accordance with some embodiments. In some embodiments, the etching stop layer 144 is made of dielectric material, such as silicon nitride (SiN), silicon oxynitride (SiON), silicon oxide (SiO₂), silicon carbide (SiC), oxygen-doped silicon carbide (SiC:O), oxygen-doped silicon carbonitride (Si(O)CN), or a combination thereof. In some embodiments, a dielectric material for the etching stop layer 144 is deposited using CVD (such as LPCVD, PECVD, HDP-CVD, or HARP), ALD, another suitable method, or a combination thereof.

A second interlayer dielectric layer 146 is formed over the etching stop layer 144, as shown in FIGS. 3E-1 and 3E-2, in accordance with some embodiments. In some embodiments, the second interlayer dielectric layer 146 is made of dielectric material, such as USG, BPSG, FSG, PSG, BSG, or another suitable dielectric material. In some embodiments, the second interlayer dielectric layer 146 and the etching stop layer 144 are made of different materials and have a great difference in etching selectivity. In some embodiments, the etching stop layer 144 is made of silicon nitride, and the second interlayer dielectric layer 146 is made of silicon oxide. In some embodiments, the second interlayer dielectric layer 146 is deposited using such as CVD (such as HDP-CVD, PECVD, HARP or FCVD), another suitable technique, or a combination thereof.

The second interlayer dielectric layer 146, the etching stop layer 144, the first interlayer dielectric layer 130 and the contact etching stop layer 129 are patterned to form contact openings 148, as shown in FIGS. 3E-1 and 3E-2, in accordance with some embodiments. The contact openings 148 correspond to and expose the frontside surfaces of the source/drain features 128N and 128P, in accordance with some embodiments.

The patterning process includes forming a photoresist (not shown) such as by using spin-on coating, and then patterning the photoresist to have opening patterns corresponding to the contact openings 148 by exposing the photoresist to light using an appropriate photomask (or reticle). Exposed or unexposed portions of the photoresist may be removed depending on whether a positive or negative resist is used. The opening patterns of the photoresist may then be transferred to the second interlayer dielectric layer 146, the etching stop layer 144, the first interlayer dielectric layer 130 and the contact etching stop layer 129, such as by using one or more suitable etch processes. The photoresist can be removed in an ashing or wet strip process, for example.

In alternative embodiments, a hard mask layer (not shown) may be formed on semiconductor structure 100. The hard mask layer may include, or be formed of, a nitrogen-free anti-reflection layer (NFARL), carbon-doped silicon dioxide (e.g., SiO₂:C), titanium nitride (TiN), titanium oxide (TiO), aluminum oxide (AlO), boron nitride (BN), a multilayer thereof, another suitable material, and/or a combination thereof. The hard mask layer may be etched using a patterned photoresist layer, which may be formed by the photolithography described above, thereby having the opening patterns corresponding to the contact openings 148. The patterned hard mask layer may transfer the opening patterns to the second interlayer dielectric layer 146, the etching stop layer 144, the first interlayer dielectric layer 130 and the contact etching stop layer 129, which may be accomplished by using one or more suitable etch processes.

The etch processes may include dry etching such as a reactive ion etch (RIE), neutral beam etch (NBE), inductive coupled plasma (ICP) etch, another suitable method, or a combination thereof. The etch processes may be anisotropic. In some embodiments, the source/drain features 128N and 128P may be recessed in the etching process.

FIGS. 3F-1 and 3F-2 illustrate the semiconductor structure 100 after the formation of contact liners 150, in accordance with some embodiments.

Contact liners 150 are formed in the contact openings 148, as shown in FIGS. 3F-1 and 3F-2, in accordance with some embodiments. The contact liners 150 extend along the sidewalls of the contact openings 148 and partially fill the contact openings 148, in accordance with some embodiments.

In some embodiments, the contact liners 150 is made of dielectric material such as silicon-containing dielectric material such as silicon nitride (SiN), silicon oxycarbide (SiOC), silicon oxynitride (SiON), silicon oxide (SiO₂), silicon carbon nitride (SiCN), silicon oxycarbonitride (SiOCN), and/or oxygen-doped silicon carbonitride (Si(O)CN), or high-k dielectric material (e.g., with dielectric constant greater than about 7.9) such as AlO, AlON, LaO, ZrO, HfO, ZnO, ZrN, ZrAlO, TiO, TaO, YO, TaCN, or a combination thereof.

In some embodiments, the formation of the contact liners 150 includes depositing the dielectric material using ALD, CVD (such as LPCVD, PECVD or HDP-CVD), another suitable method, and/or a combination thereof, and etching-back the dielectric material to remove the dielectric material from the top surface of the second interlayer dielectric layer 146 and the bottom surface of the contact openings 148. The top surfaces of the source/drain features 128N and 128P are exposed from the contact openings 148 again, in accordance with some embodiments.

FIGS. 3G-1 and 3G-2 illustrate the semiconductor structure 100 after the formation of a sacrificial layer 152, in accordance with some embodiments.

A sacrificial layer 152 is formed on the semiconductor structure 100, as shown in FIGS. 3G-1 and 3G-2, in accordance with some embodiments. The sacrificial layer 152 extends along the top surface of the second interlayer dielectric layer 148, the sidewalls of the contact liners 150, and the top surfaces of the source/drain features 128N and 128P exposed from the contact opening 148, and partially fills the contact openings 148, in accordance with some embodiments.

In some embodiments, the sacrificial layer 152 is made of dielectric material such as silicon-containing dielectric material such as silicon nitride (SiN), silicon oxycarbide (SiOC), silicon oxynitride (SiON), silicon oxide (SiO₂), silicon carbon nitride (SiCN), silicon oxycarbonitride (SiOCN), and/or oxygen-doped silicon carbonitride (Si(O)CN), or high-k dielectric material (e.g., with dielectric constant greater than about 7.9) such as AlO, AlON, LaO, ZrO, HfO, ZnO, ZrN, ZrAlO, TiO, TaO, YO, TaCN, or a combination thereof. In some embodiments, the sacrificial layer 152 and the contact liners 150 are made of different materials and have a great difference in etching selectivity. In some embodiments, the sacrificial layer 152 is deposited using ALD, CVD (such as LPCVD, PECVD or HDP-CVD), another suitable method, and/or a combination thereof.

FIGS. 3H-1 and 3H-2 illustrate the semiconductor structure 100 after an etching process, in accordance with some embodiments.

An etching process is performed on the semiconductor structure 100 to vertically enlarge the contact openings 148, as shown in FIGS. 3H-1 and 3H-2, in accordance with some embodiments. The etching process first removes the portions of the sacrificial layer 152 along the top surface of the second interlayer dielectric layer 148 and the top surfaces of the source/drain features 128N and 128P, and then etches the source/drain features 128N and 128P, thereby extending the contact openings 148 to a deeper position, in accordance with some embodiments. The enlarged contact openings 148 are denoted as 148′. The etching processes may include an anisotropic etching process such as dry plasma etching, an isotropic etching process such as dry chemical etching, remote plasma etching or wet chemical etching, or a combination thereof.

In some embodiments, the bottom surfaces of the contact openings 148′ are located lower than the bottom surfaces of the second topmost nanostructures 108. In some other embodiments, the bottom surfaces of the contact openings 148′ are located higher than or equal to the bottom surfaces of the second topmost nanostructures 108.

FIGS. 3I-1 and 3I-2 illustrate the semiconductor structure 100 after the removal of the sacrificial layer 152, in accordance with some embodiments.

An etching process is performed on the semiconductor structure 100 to remove the sacrificial layer 152, thereby exposing the sidewalls of the contact liners 150 and laterally enlarging the contact openings 148′, as shown in FIGS. 3I-1 and 3I-2, in accordance with some embodiments. The contact liner 150 is exposed from the contact openings 148′, in accordance with some embodiments. The etching processes may include an anisotropic etching process such as dry plasma etching, an isotropic etching process such as dry chemical etching, remote plasma etching or wet chemical etching, or a combination thereof.

The contact openings 148′ have kinked profiles, in accordance with some embodiments. As the term is used herein, “kink” refers to a pattern extending in a direction, with a dent or protrusion on one or both sides of the pattern. The contact openings 148′ with a kink structure may include narrower portions and wider portions, in accordance with some embodiments. The contact openings 148′ includes an upper portion (wider portions) 148A and a lower portion (narrower portions) 148B, in accordance with some embodiments.

The upper portions 148A penetrate through the second interlayer dielectric layer 146, the etching stop layer 144, the first interlayer dielectric layer 130, the contact etching stop layer 129 and extends to the top portion of the source/drain features 128N and 128P, in accordance with some embodiments. The lower portions 148B penetrate through the upper portion of source/drain features 128N and 128P, in accordance with some embodiments.

In some embodiments, the sidewalls of the upper portion 148A are substantially straight or linear. In some embodiments, the sidewalls of the upper portion 148A are sloped relative to or substantially perpendicular to a plane parallel to the top surface of the substrate 102. In some embodiments, the sidewalls of the lower portion 148B are substantially straight or linear. In some embodiments, the sidewalls of the lower portion 148B are substantially perpendicular to the plane parallel to the top surface of the substrate 102.

The contact opening 148′ has a connecting wall 148W which is connected to the sidewall of the upper portion 148A and the sidewall of the lower portion 148B, in accordance with some embodiments. In some embodiments, the connecting wall 148W extends horizontally. In some other embodiments, the connecting wall 148W extends obliquely to the plane parallel to the top surface of the substrate 102. As a result, the sidewall of the lower portion 148B is not coplanar with the sidewall of the upper portion 148A. The sidewall of the lower portion 148B is indented from the sidewall of the upper portion 148A by a distance that is the distance the connecting wall extends horizontally, in accordance with some embodiments.

In some embodiments, the dimension of the upper portion 148A in the X direction and Y direction decreases or maintains consistent in the direction toward the bottom of the contact opening 148′. In some embodiments, the dimension of the lower portion 148B in the X direction and Y maintains consistent in the direction toward the bottom of the contact opening 148′.

In some embodiments, the dimension A1 of the upper portion 148A in the X direction at the bottom of the upper portion 148A (where the connecting wall 148W is located) is greater than the dimension B1 of the lower portion 148B in the X direction at the top of the lower portion 148B (where the connecting wall 148W is located). In some embodiments, the dimension A2 of the upper portion 148A in the Y direction at the bottom of the upper portion 148A (where the connecting wall 148W is located) is greater than the dimension B2 of the lower portion 148B in the Y direction at the top of the lower portion 148B (where the connecting wall 148W is located).

FIGS. 3J-1 and 3J-2 illustrate the semiconductor structure 100 after the formation of contact structures 156, in accordance with some embodiments.

Silicide layers 154 are formed on the exposed surfaces of the source/drain features 128N and 128P, as shown in FIGS. 3J-1 and 3J-2, in accordance with some embodiments. In some embodiments, the silicide layers 154 are made of WSi, NiSi, TiSi and/or CoSi. In some embodiments, the formation of the silicide layers 154 includes depositing a metal material followed by one or more annealing processes. The semiconductive material (e.g., Si or SiGe) from the source/drain features 128N and 128P reacts with the metal material to form the silicide layers 154, in accordance with some embodiments. The unreacted metal material is then removed using a cleaning process.

Frontside contact structures 156 are formed in the contact opening 148′ on the silicide layers 154, as shown in FIGS. 3J-1 and 3J-2, in accordance with some embodiments. The contact structures 156 land on the source/drain features 128N and 128P and extends into the source/drain features 128N and 128P, in accordance with some embodiments.

The contact structures 156 may have a multilayer structure. For example, one or more conductive materials include a barrier/adhesive layer and a metal bulk layer on the barrier/adhesive layer. In some embodiments, the barrier/adhesive layer may be made of tantalum (Ta), tantalum nitride (TaN), titanium (Ti), titanium nitride (TiN), cobalt tungsten (CoW), another suitable material, or a combination thereof. In some embodiments, the metal bulk layer is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

In some embodiments, one or more conductive materials are deposited using CVD, PVD, e-beam evaporation, ALD, electroplating (ECP), electroless deposition (ELD), another suitable method, or a combination thereof to overfill the contact openings. In some embodiments, the metal bulk layer is formed using a selective deposition technique such as cyclic CVD process or ELD process, and it is not necessary to form the barrier/adhesive layer before depositing the metal bulk material. The one or more conductive materials over the upper surface of the second interlayer dielectric layer 146 are planarized using, for example, CMP. In some other embodiments, the planarization process is performed until the gate electrode layer 142 is exposed.

A deep extension of the contact structures 156 may reduce the parasitic resistance (Rp) of the resulting semiconductor device, and may increase the landing area of the contact structure 156 with the bulk layer L2 of the source/drain features 128N and 128P, and/or reduce the current path. As the scale of the semiconductor devices continues to shrink, the critical dimension of the contact structures becomes smaller and smaller. Due to the characteristics of the etching process, the larger the critical dimension of the contact opening (or opening pattern), the greater the etching amount. To form deeper contact openings in an etching process, the contact openings need to be defined with a larger critical dimension. However, the contact openings with a larger critical dimension may cause the resulting contact structures and/or silicide layers to touch barrier layers of the source/drain features over a large area. Due to the low dopant concentration of the barrier layers, the contact between the contact structures (and/or silicide layers) and the barrier layers may increase the contact resistance between the contact structure and the source/drain features (Rcsd) and/or the channel resistance (Rch). Therefore, it may be difficult to simultaneously reduce the parasitic resistance (Rp) and the source/drain features (Rcsd) of the resulting semiconductor device.

In accordance with the embodiments of the present disclosure, the contact openings 148′ are formed using two separate etching processes which are respectively performed before and after the formation of the contact liner 150. As a result, the frontside contact structure 156 may extend to a deep position while preventing the contact structure from coming into contact with the barrier layers L1, or reduce the contact area between the contact structure 156 (or the silicide layer 154) and the barrier layers L1. In addition, the risk of leakage between the contact structure 156 and the final gate stack 136, which is caused by the variation in the thickness of the inner spacer layers 122, may be reduced. Therefore, the performance and/or the reliability of the resulting semiconductor devices may be enhanced, e.g., higher DC performance and/or lower leakage.

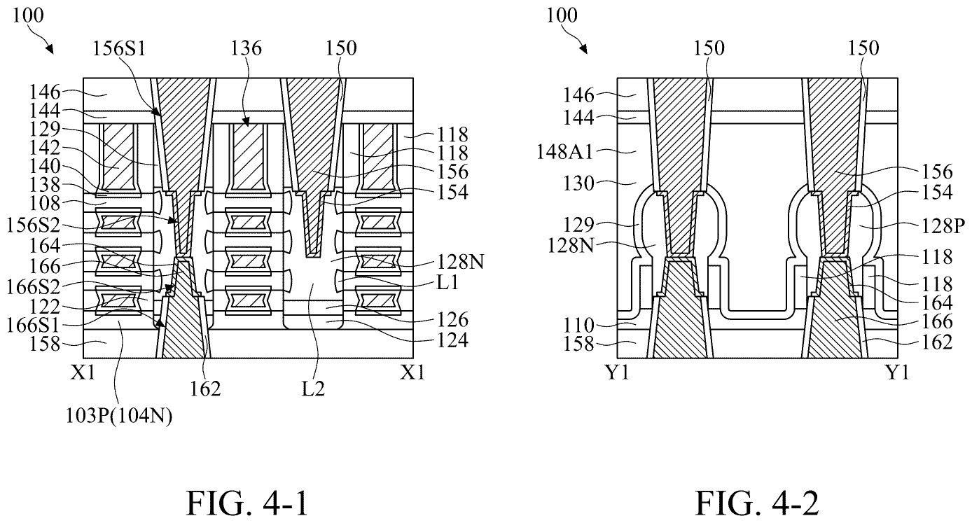

FIGS. 3J-3 and 3J-4 are respective enlarged views of FIGS. 3J-1 and 3J-2 to illustrate more detail of the contact structure 156, in accordance with some embodiments of the disclosure.

The contact structure 156 has a kinked profile, in accordance with some embodiments. The contact structures 156 with the kink structure may include narrower portions and wider portions, in accordance with some embodiments. The contact structure 156 includes an upper portion (wider portion) 156A and a lower portion (narrower portion) 156B, in accordance with some embodiments.

The upper portion 156A penetrates through the second interlayer dielectric layer 146, the etching stop layer 144, the first interlayer dielectric layer 130, the contact etching stop layer 129 and extends to the top portion of the source/drain features 128N and 128P, in accordance with some embodiments. The bottom of the upper portion 156A is substantially level with the bottom of the contact liners 150, in accordance with some embodiments. The lower portions 156B penetrate through the upper portion of source/drain features 128N and 128P, in accordance with some embodiments. In some embodiments, the bottom surface of the lower portion 156B is lower than the bottom surfaces of the second topmost nanostructures 108. In some other embodiments, the bottom surface of the lower portion 156B is located higher than or equal to the bottom surfaces of the second topmost nanostructures 108.

In some embodiments, the sidewalls 156S1 of the upper portion 156A are substantially straight or linear. In some embodiments, the sidewalls 156S1 of the upper portion 156A are sloped relative to or substantially perpendicular to the plane parallel to the top surface of the substrate 102. In some embodiments, the sidewalls 156S2 of the lower portion 156B are substantially straight or linear. In some embodiments, the sidewalls 156S2 of the lower portion 156B are substantially perpendicular to the plane parallel to the top surface of the substrate 102.

The contact structure 156 has a connecting wall 156W which is connected to the sidewall 156S1 of the upper portion 156A and the sidewall 156S2 of the lower portion 156B, in accordance with some embodiments. In some embodiments, the connecting wall 156W extends horizontally. In some other embodiments, the connecting wall 156W extends obliquely to the plane parallel to the top surface of the substrate 102. As a result, the sidewall 156S2 of the lower portion 156B is not coplanar with the sidewall 156S1 of the upper portion 156A. The sidewall 156S2 of the lower portion 156B is indented from the sidewall 156S1 of the upper portion 156A by a distance that is the distance the connecting wall 156W extends horizontally, in accordance with some embodiments. In some embodiments, the connecting wall 156W is located at a position higher than the top surface of the topmost nanostructure 108. In some other embodiments, the connecting wall 156W may be located at a position lower than the top surface of the topmost nanostructure 108.

In some embodiments, the dimension of the upper portion 156A in the X direction and Y direction decreases or maintains consistent in the direction toward the bottom of the contact structure 156. For example, the upper portion 156A has a dimension D1 in the X direction at the top of the upper portion 156A and a dimension D2 in the X direction at the bottom of the upper portion 156A (where the connecting wall 156W is located). The dimension D2 is equal to or less than the dimension D1. For example, the upper portion 156A has a dimension D5 in the Y direction at the top of the upper portion 156A and a dimension D6 in the Y direction at the bottom of the upper portion 156A. The dimension D6 is equal to or less than the dimension D5.

In some embodiments, the dimension of the lower portion 156B in the X direction and Y maintains consistent in the direction toward the bottom of the contact structure 156. For example, the lower portion 156B has a dimension D3 in the X direction at the top of the lower portion 156B (where the connecting wall 156W is located) and a dimension D4 in the X direction at the bottom of the lower portion 156B. The dimension D3 is substantially equal to the dimension D4, and less than the dimension D2 by about 1-10 nm. In some embodiments, the dimension D2 is in a range from about 3 nm to about 50 nm. In some embodiments, the dimension D3 is in a range from about 3 nm to about 50 nm. In some embodiments, the ratio (D2/D3) of the dimension D2 to the dimension D3 is in a range from about 1.1 to about 2.

For example, the lower portion 156B has a dimension D7 in the Y direction at the top of the lower portion 156B and a dimension D8 in the Y direction at the bottom of the lower portion 156B. The dimension D7 is substantially equal to the dimension D8, and less than the dimension D6 by about 1-10 nm. In some embodiments, the ratio (D6/D7) of the dimension D6 to the dimension D3 is in a range from about 1.1 to about 2.

In some embodiments, the difference (D2−D3) between the dimension D3 and dimension D2 is substantially equal to the difference (D6−D7) between the dimension D6 and dimension D7, or the difference (|(D2−D3)−(D6−D7)|) is less than 1 nm. In some other embodiments, one or more directional implantation process(es) may be performed on the contact liners 150 and/or the sacrificial layer 152 and followed by an etching process. As a result, the thickness(es) of the portions of the contact liners 150 and/or the sacrificial layer 152 extending in the X direction (the portions in FIGS. 3H-2) is thinner than the thickness(es) of the portions of the contact liners 150 and/or the sacrificial layer 152 extending in the Y direction (the portions in FIGS. 3H-1). Therefore, the difference ((D2−D3)−(D6−D7)) may be greater than about 1 nm and less than about 10 nm.

In some embodiments, the upper portion 156A has a height H1 (the dimension in the Z direction) in a range from about 8 nm to about 50 nm. In some embodiments, the lower portion 156B has a height H2 (the dimension in the Z direction) in a range from about 3 nm to about 50 nm. In some embodiments, the ratio (H1/H2) of the height H1 to the height H2 is in a range from about 0.1 to about 10.

In some embodiments, the slope of the sidewall 156S2 is greater than the slope of the sidewall 156S1. That is, in the direction toward the backside of the semiconductor structure 100, the rate at which the width of the upper portion 156A decreases is greater than the rate at which the width of the lower portion 156B decreases.

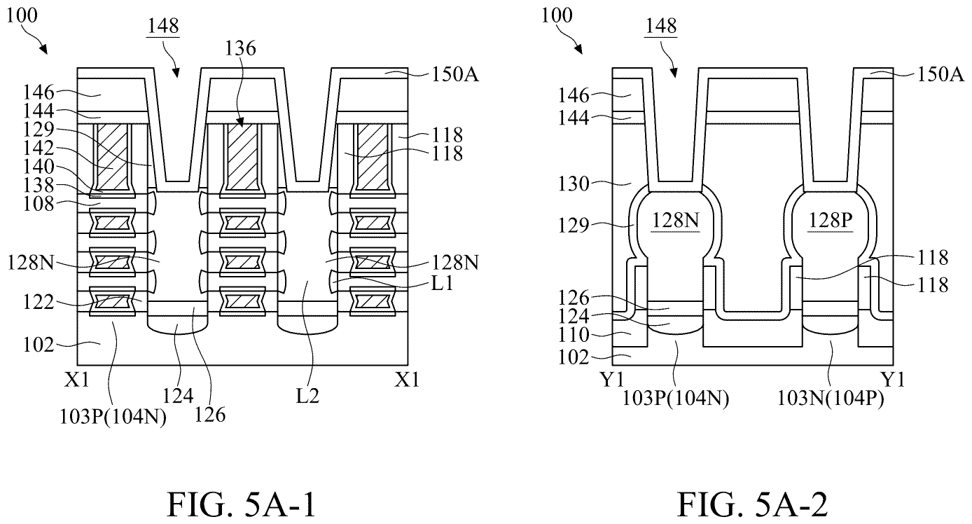

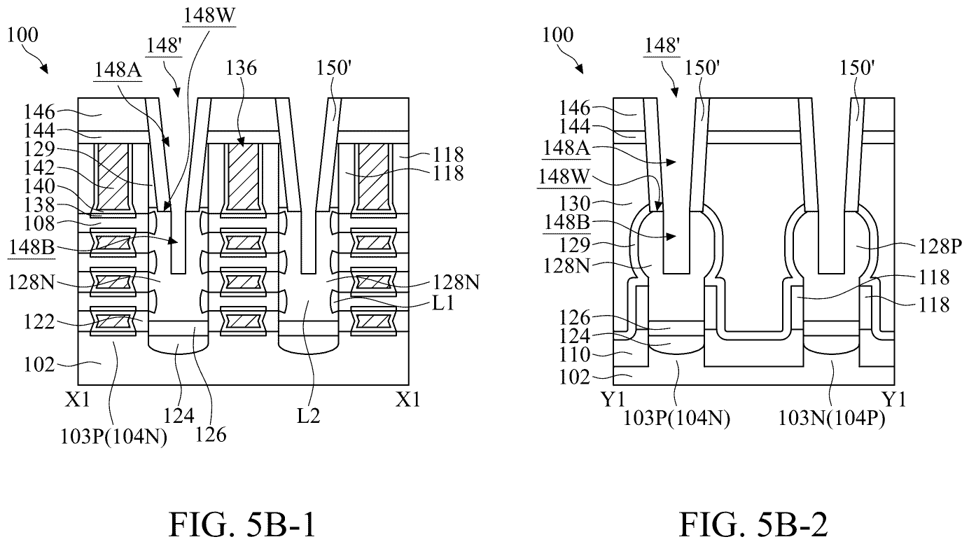

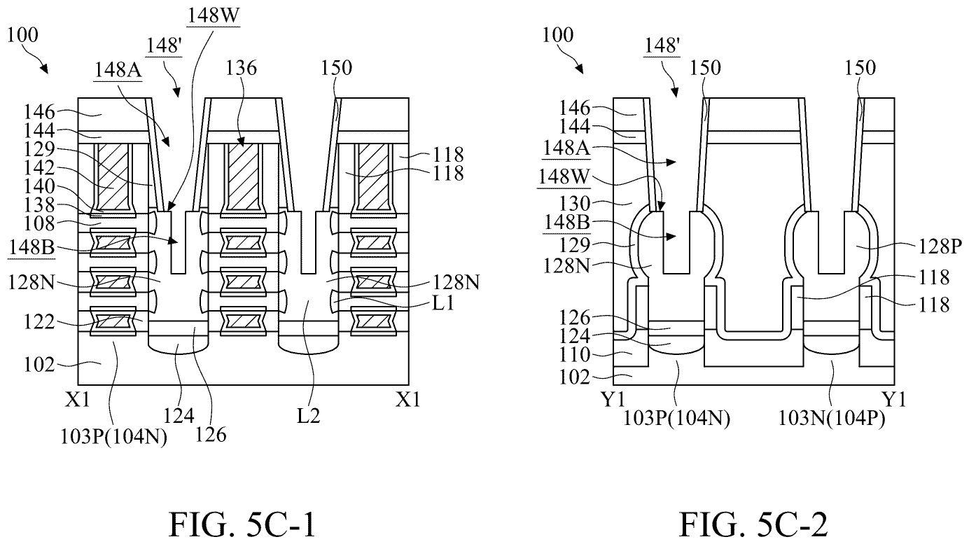

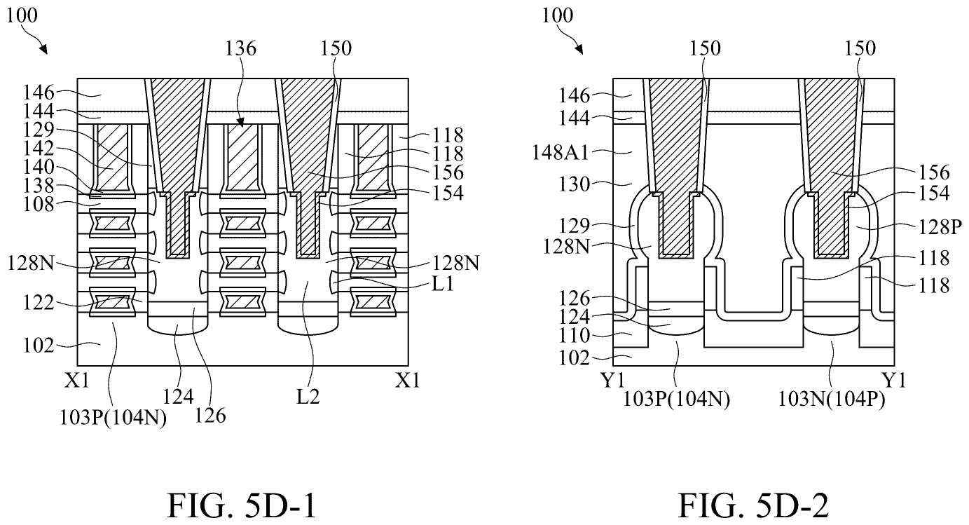

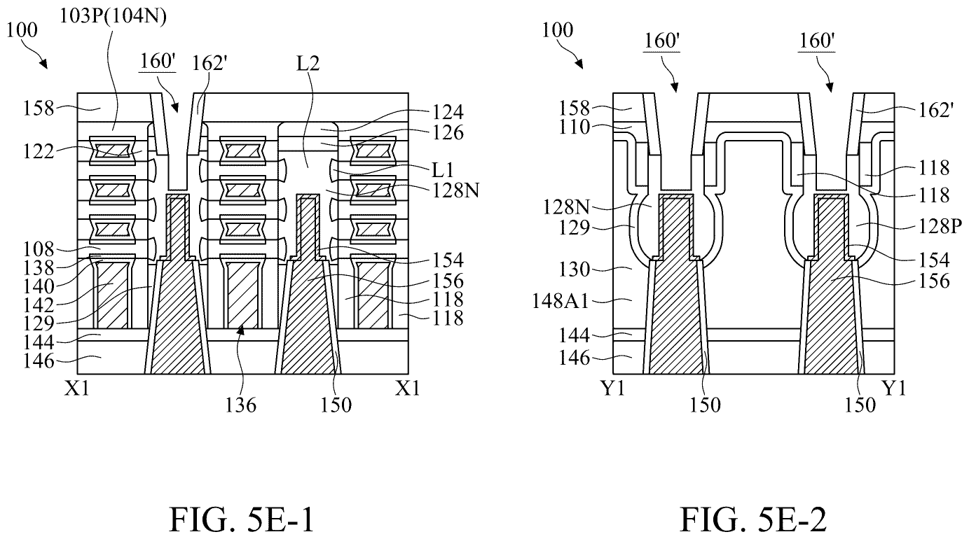

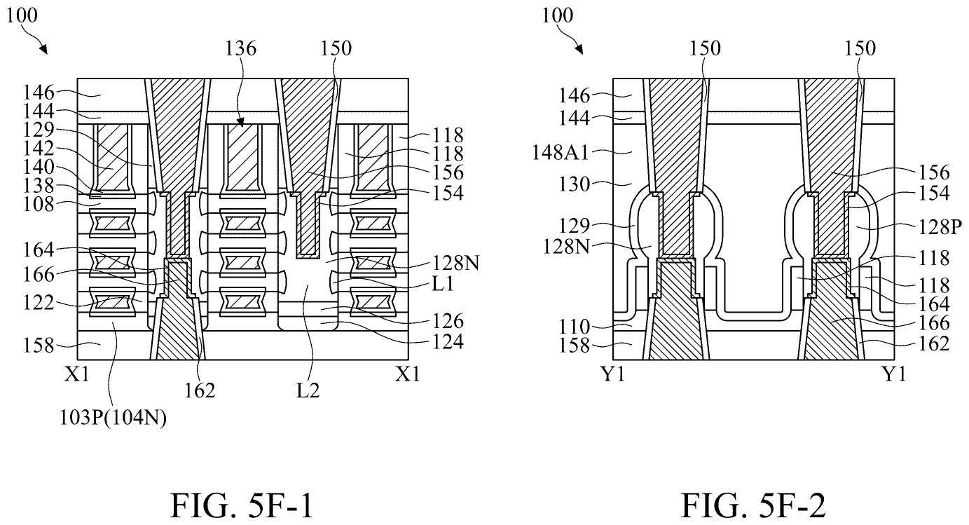

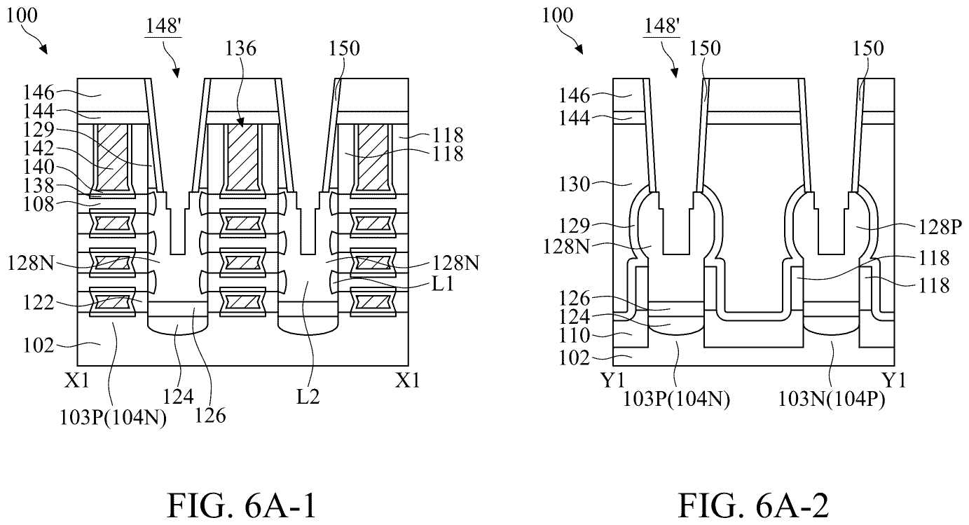

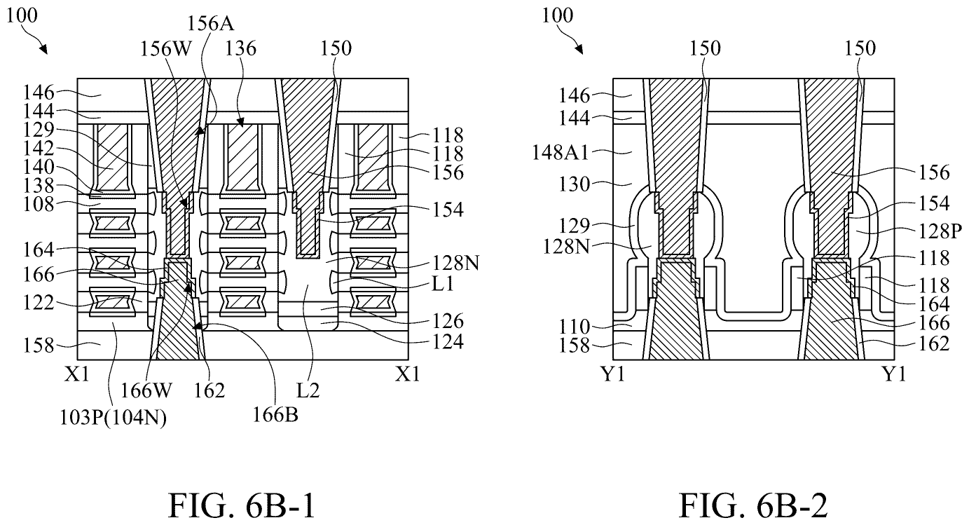

FIGS. 3J-5 and 3J-6 are modifications of the semiconductor structure of FIGS. 3J-3 and 3J-4, in accordance with some embodiments of the disclosure. The contact structure 156 further includes a middle portion 156C between the upper portion 156A and the lower portion 156B, as shown in FIGS. 3J-5 and 3J-6, in accordance with some embodiments. The sidewalls of the middle portion 156C are the connecting wall 156W which extends obliquely to the plane parallel to the top surface of the substrate 102.

The slope of the connecting wall 156W is less than the slope of the sidewall 156S1 and the slope of the sidewall 156S2. That is, in the direction toward the backside of the semiconductor structure 100, the rate at which the width of the middle portion 156C decreases is greater than the rate at which the width of the upper portion 156A decreases and the rate at which the width of the lower portion 156B decreases.

The semiconductor structure 100 may undergo further frontside BEOL processes to form various interconnection conductive features (not shown) over the semiconductor structure 100, such as vias to contact structures and/or to gate stacks, frontside metal layers and vias between neighboring two metal layers.

FIGS. 3I-1 and 3I-2 illustrate the semiconductor structure 100 after flipping the semiconductor structure 100, a planarization process and the formation of a third interlayer dielectric layer 158, in accordance with some embodiments.

The semiconductor structure 100 is flipped upside down, as shown FIGS. 3K-1 and 3K-2, in accordance with some embodiments. In some embodiments, a carrier substrate (not shown) may be formed over and seal the frontside of the semiconductor structure 100 before flipping the semiconductor structure 100 to protect the components of the semiconductor structure 100 during subsequent backside processes. After flipping the semiconductor structure 100, the backside surface of the substrate 102 (the backside of the semiconductor structure 100) faces upward, in accordance with some embodiments.

The substrate 102 is removed from the backside of the semiconductor structure 100 using a planarization process such as a grinding process, a CMP process, an etching process, or a combination thereof until the isolation structure 110 is exposed, as shown in FIGS. 3K-1 and 3K-2, in accordance with some embodiments. In some embodiments, the first separation layers 124 are exposed. A third interlayer dielectric layer 158 is deposited over the semiconductor structure 100 using CVD or ALD process, as shown in FIGS. 3K-1 and 3K-2, in accordance with some embodiments. In some embodiments, the material of the fourth interlayer dielectric layer 158 may be the same as or similar to the material of the first interlayer dielectric layer 130.

FIGS. 3L-1 and 3N-2 illustrate the formation of backside contact structures 166, in accordance with some embodiments. The steps for forming the backside contact structures 166 may be similar to the steps for forming the frontside contact structures 156. FIGS. 3L-1 and 3L-2 illustrate the semiconductor structure 100 after the formation of contact openings 160, in accordance with some embodiments.

The third interlayer dielectric layer 150, the second separation layers 126 and the first separation layers 124 are patterned to form contact openings 160, as shown in FIGS. 3L-1 and 3L-2, in accordance with some embodiments. The contact openings 160 correspond to and expose the backside surfaces of the source/drain features 128N and 128P used for the source terminals, in accordance with some embodiments. The patterning process may be similar to the patterning process for forming the contact openings 148.

FIGS. 3M-1 and 3M-2 illustrate the semiconductor structure 100 after the formation of contact liners 162 and sacrificial layers 163 and an etching process, in accordance with some embodiments.

Contact liners 162 and sacrificial layers 163 are sequentially formed in the contact openings 160 to partially fill the contact openings 160, and an etching process is performed on the semiconductor structure 100 to vertically enlarge the contact openings 160, as shown in FIGS. 3M-1 and 3M-2, in accordance with some embodiments. In some embodiments, the formation and the material of the contact liners 162 and the sacrificial layers 163 may be the same as or similar to the formation and the material of the contact liners 150 and the sacrificial layers 152, respectively.

The etching process etches the source/drain features 128N and 128P, thereby extending the contact openings 160 to a deeper position, in accordance with some embodiments. The enlarged contact openings 160 is denoted as 160′. In some embodiments, the contact openings 160′ may extend to expose the silicide layers 154.

FIGS. 3N-1 and 3N-2 illustrate the semiconductor structure 100 after the removal of the sacrificial layers 163 and the formation of contact structures 166, in accordance with some embodiments. FIGS. 3N-1 and 3N-2 illustrate that the frontside of the semiconductor structure 100 faces upward.

An etching process is performed on the semiconductor structure 100 to remove the sacrificial layer 163, silicide layers 164 are formed on the exposed surfaces of the source/drain features 128N and 128P, and backside contact structures 166 are formed in the contact opening 160′ on the silicide layers 164, as shown in FIGS. 3N-1 and 3N-2, in accordance with some embodiments. In some embodiments, the formation and the material of the silicide layers 164 and the contact structures 166 may be the same as or similar to the formation and the material of the silicide layers 154 and the contact structures 156.

In accordance with the embodiments of the present disclosure, the contact openings 160′ are formed using two separate etching processes which are respectively performed before and after the formation of the contact liner 162. As a result, the backside contact structure 166 may extend to a deep position while preventing the backside contact structure from coming into contact with the barrier layers L1, or mitigate the contact area between the contact structure (or the silicide layer) and the barrier layers L1. In addition, the risk of leakage between the contact structure 166 and the final gate stack 136, which is caused by the variation in the thickness of the inner spacer layers 122, may be reduced. Therefore, the performance and/or the reliability of the resulting semiconductor devices may be enhanced, e.g., higher DC performance and/or lower leakage.

Furthermore, because the silicide 154 is in direct contact with the silicide 156, the backside contact structure 166 is electrically connected the frontside contact structure 156 without through the bulk layer of the source/drain feature. Therefore, the contact resistance may be further reduced. In some other embodiments, the backside contact structure 166 may be in direct contact with the frontside contact structure 156.

FIGS. 3N-3 and 3N-4 are respective enlarged views of FIGS. 3N-1 and 3N-2 to illustrate more detail of the contact structure 166, in accordance with some embodiments of the disclosure.

The contact structure 166 has a kinked profile, in accordance with some embodiments. The contact structures 166 with the kink structure may include narrower portions and wider portions, in accordance with some embodiments. The contact structure 166 includes an upper portion (narrower portion) 166A and a lower portion (wider portion) 166B, in accordance with some embodiments.

The lower portions 166B penetrate through the third interlayer dielectric layer 158, the second separation layers 126 and the first separation layers 124 and extends to the bottom portion of the source/drain features 128N and 128P, in accordance with some embodiments. The top of the lower portion 166B is substantially level with the top of the contact liners 162, in accordance with some embodiments. The upper portions 166A penetrate through the lower portions of source/drain features 128N and 128P, in accordance with some embodiments.

In some embodiments, the sidewalls 166S1 of the lower portion 166B are substantially straight or linear. In some embodiments, the sidewalls 166S1 of the lower portion 166B are sloped relative to or substantially perpendicular to the horizontal plane (parallel to the top surface of substrate 102 that has been removed). In some embodiments, the sidewalls 166S2 of the upper portion 166A are substantially straight or linear. In some embodiments, the sidewalls 166S2 of the upper portion 166A are substantially perpendicular to the horizontal plane parallel.

The contact structure 166 has a connecting wall 166W which is connected to the sidewall 166S1 of the lower portion 166B and the sidewall 166S2 of the upper portion 166A, in accordance with some embodiments. In some embodiments, the connecting wall 166W extends horizontally. In some other embodiments, the connecting wall 166W extends obliquely to the horizontal plane. As a result, the sidewall 166S2 of the upper portion 166A is not coplanar with the sidewall 166S1 of the lower portion 166B. The sidewall 166S2 of the upper portion 166A is indented from the sidewall 166S1 of the lower portion 166B by a distance that is the distance the connecting wall 166W extends horizontally, in accordance with some embodiments. In some embodiments, the connecting wall 166W is located at a position lower than the bottom surface of the bottommost nanostructure 108. In some other embodiments, the connecting wall 166W may be located at a position higher than the bottom surface of the bottommost nanostructure 108.

In some embodiments, the dimension of the upper portion 166A in the X direction and Y maintains consistent in the direction toward the bottom (i.e., backside surface) of the contact structure 166. For example, the upper portion 166A has a dimension D9 in the X direction at the top of the upper portion 166A and a dimension D10 in the X direction at the bottom of the upper portion 166A (where the connecting wall 166W is located). The dimension D9 is substantially equal to the dimension D10. For example, the upper portion 166A has a dimension D13 in the Y direction at the top of the upper portion 166A and a dimension D14 in the Y direction at the bottom of the 166A. The dimension D13 is substantially equal to the dimension D14.

In some embodiments, the dimension of the lower portion 166B in the X direction and Y direction increases or maintains consistent in the direction toward the bottom of the contact structure 166. For example, the lower portion 166B has a dimension D11 in the X direction at the top of the lower portion 166B (where the connecting wall 156W is located) and a dimension D12 in the X direction at the bottom of the lower portion 166B. The dimension D12 is equal to or greater than the dimension D11. The dimension D10 is less than the dimension D11 by about 1-10 nm. In some embodiments, the dimension D10 is in a range from about 3 nm to about 50 nm. In some embodiments, the dimension D11 is in a range from about 3 nm to about 50 nm. In some embodiments, the ratio (D11/D10) of the dimension D11 to the dimension D10 is in a range from about 1.1 to about 2.

For example, the lower portion 166B has a dimension D15 in the Y direction at the top of the lower portion 166B and a dimension D16 in the Y direction at the bottom of the lower portion 166B. The dimension D16 is equal to or greater than the dimension D15. The dimension D14 is less than the dimension D15 by about 1-10 nm. In some embodiments, the ratio (D15/D14) of the dimension D15 to the dimension D14 is in a range from about 1.1 to about 2.

In some embodiments, the difference (D11−D10) between the dimension D11 and dimension D10 is substantially equal to the difference (D15−D14) between the dimension D15 and dimension D14, or the difference (|(D11−D10)−(D15−D14)|) is less than 1 nm.

In some other embodiments, one or more directional implantation process(es) may be performed on the contact liners 162 and/or the sacrificial layer 163 and followed by an etching process. As a result, the thickness(es) of the portions of contact liners 162 and/or the sacrificial layer 163 extending in the X direction (the portions in FIGS. 3M-2) is thinner than the thickness(es) of the portions of the contact liners 162 and/or the sacrificial layer 163 extending in the Y direction (the portions in FIGS. 3N-1). Therefore, the difference ((D11−D10)−(D15−D14)) may be greater than about 1 nm and less than about 10 nm.

In some embodiments, the dimension D11 of the backside contact structures 166 is greater than the dimension D2 (FIG. 3J-3) of the frontside contact structure 156 by about 1-10 nm. In some embodiments, the dimension D10 of the backside contact structures 166 is greater than the dimension D3 (FIG. 3J-3) of the frontside contact structure 156 by about 1-10 nm.

In some embodiments, the dimension D15 of the backside contact structures 166 is greater than the dimension D6 (FIG. 3J-4) of the frontside contact structure 156 by about 1-10 nm. In some embodiments, the dimension D14 of the backside contact structures 166 is greater than the dimension D7 (FIG. 3J-4) of the frontside contact structure 156 by about 1-10 nm.

In some embodiments, the upper portion 166A has a height H3 (the dimension in the Z direction) in a range from about 3 nm to about 50 nm. In some embodiments, the lower portion 166B has a height H4 (the dimension in the Z direction) in a range from about 8 nm to about 50 nm. In some embodiments, the ratio (H4/H3) of the height H4 to the height H3 is in a range from about 0.1 to about 10.

In some embodiments, the slope of the sidewall 166S2 is greater than the slope of the sidewall 166S1. That is, in the direction toward the frontside of the semiconductor structure 100, the rate at which the width of the lower portion 166B decreases is greater than the rate at which the width of the upper portion 166A decreases.

FIGS. 3N-5 and 3N-6 are modifications of the semiconductor structure of FIGS. 3N-3 and 3N-4, in accordance with some embodiments of the disclosure. The contact structure 166 further includes a middle portion 166C between the upper portion 166A and the lower portion 166B, as shown in FIGS. 3N-5 and 3N-6, in accordance with some embodiments. The sidewalls of the middle portion 166C are the connecting wall 156W which extends obliquely to the horizontal plane.

The slope of the connecting wall 166W is less than the slope of the sidewall 166S1 and the slope of the sidewall 166S2. That is, in the direction toward the frontside of the semiconductor structure 100, the rate at which the width of the middle portion 166C decreases is greater than the rate at which the width of the upper portion 166A decreases and the rate at which the width of the lower portion 166B decreases.

The semiconductor structure 100 may undergo further backside BEOL processes to form various interconnection conductive features (not shown) over the semiconductor structure 100, such as backside metal layers and vias between neighboring two metal layers.

FIGS. 4-1 and 4-2 are cross-sectional views of the semiconductor structure corresponding to lines X1-X1 and Y1-Y1 of FIG. 2, in accordance with some embodiments of the disclosure. The embodiments of FIGS. 4-1 and 4-2 are similar to the embodiments of FIGS. 3A-1 to 3N-2, except that the lower portion of the contact structure 156 has tapered sidewalls and the upper portion of the contact structure 166 has tapered sidewalls. In some embodiments, the slope of the sidewall 156S2 is equal to or different than the slope of the sidewall 156S1. In some embodiments, the slope of the sidewall 166S2 is equal to or different than the slope of the sidewall 166S1.

FIGS. 5A-1 through 5F-2 are cross-sectional views illustrating the formation of the semiconductor structure 100 of FIG. 2 at various intermediate stages, in accordance with some embodiments of the disclosure. The figures ending with “−1” correspond to line X1-X1 shown in FIG. 2. The figures ending with “−2” correspond to line Y1-Y1 shown in FIG. 2. The embodiments of FIGS. 5A-1 through 5F-2 are similar to the embodiments of FIGS. 3A-1 to 3N-2, except that the sacrificial layers 152 and 162 are omitted and a dielectric material for the contact liners 150 is thicker.

Continuing from FIGS. 3E-1 and 3E-2, a dielectric material 150A for the contact liners is deposited on the semiconductor structure 100, as shown in FIGS. 5A-1 and 5A-2, in accordance with some embodiments. An etching process is performed on the semiconductor structure 100 to vertically enlarge the contact openings 148, as shown in FIGS. 5B-1 and 5B-2, in accordance with some embodiments. The etching process first removes the portions of the dielectric material 150′ along the top surface of the second interlayer dielectric layer 148 and the top surfaces of the source/drain features 128N and 128P, and then etches the source/drain features 128N and 128P, thereby extending the contact openings 148 to a deeper position, in accordance with some embodiments. The enlarged contact openings 148 is denoted as 148′. The remaining dielectric material 150A is referred to as contact liners 150′.

An etching process is performed to thin down the contact liners 150′, thereby laterally enlarging the contact openings 148′, as shown in FIGS. 5C-1 and 5C-2, in accordance with some embodiments. The thinned-down contact liners 150′ are denoted as the contact liners 150. The etching processes may include an anisotropic etching process such as dry plasma etching, an isotropic etching process such as dry chemical etching, remote plasma etching or wet chemical etching, or a combination thereof.

Silicide layers 154 are formed on the exposed surfaces of the source/drain features 128N and 128P, and frontside contact structures 156 are formed in the contact opening 148′ on the silicide layers 154, as shown in FIGS. 5D-1 and 5D-2, in accordance with some embodiments. The contact structure 156 has a kinked profile that is discussed in detail above, and will not be repeated for clarity, in accordance with some embodiments.

The step described above in FIGS. 3K-1 and 3L-2 are performed, thereby forming contact opening 160, as shown in FIGS. 5E-1 and 5E-2, in accordance with some embodiments. Similar to the steps described in FIGS. 5A-1 to 5B-2, contact liners 162′ are formed in the contact opening 148 on the semiconductor structure 100, and then an etching process is performed on the semiconductor structure 100 to vertically enlarge the contact openings 160. as shown in FIGS. 5E-1 and 5E-2, in accordance with some embodiments.

An etching process is performed to thin down the contact liners 162′, thereby laterally enlarging the contact openings 160′, as shown in FIGS. 5F-1 and 5F-2, in accordance with some embodiments. The thinned-down contact liners 162′ are denoted to as the contact liners 162.

Silicide layers 164 are formed on the exposed surfaces of the source/drain features 128N and 128P, and backside contact structures 166 are formed in the contact opening 160′ on the silicide layers 164, as shown in FIGS. 5F-1 and 5F-2, in accordance with some embodiments. The contact structure 166 has a kinked profile that is discussed in detail above, and it not repeat for the clarity, in accordance with some embodiments.

FIGS. 6A-1 through 6B-2 are cross-sectional views illustrating the formation of the semiconductor structure 100 of FIG. 2 at various intermediate stages, in accordance with some embodiments of the disclosure. The figures ending with “−1” correspond to line X1-X1 shown in FIG. 2. The figures ending with “−2” correspond to line Y1-Y1 shown in FIG. 2. The embodiments of FIGS. 6A-1 through 6B-2 are similar to the embodiments of FIGS. 3A-1 to 3N-2, except that the source/drain features 128N and 128P are further laterally recessed.

Continuing from FIGS. 3I-1 and 3I-2, after the sacrificial layer 152 is removed, an etching process is performed to laterally recess the source/drain features 128N and 128P, thereby laterally enlarging the contact openings 148′, as shown in FIGS. 6A-1 and 6A-2, in accordance with some embodiments.

Silicide layers 154 are formed on the exposed surfaces of the source/drain features 128N and 128P, and backside contact structures 156 are formed in the contact opening 148′ on the silicide layers 154, as shown in FIGS. 6B-1 and 6B-2, in accordance with some embodiments.

Similarly, after the sacrificial layers 163 are removed, an etching process is performed to laterally recess the source/drain features 128N and 128P, thereby laterally enlarging the contact openings 160′, in accordance with some embodiments. Silicide layers 164 are formed on the exposed surfaces of the source/drain features 128N and 128P, and backside contact structures 166 are formed in the contact opening 160′ on the silicide layers 164, as shown in FIGS. 6B-1 and 6B-2, in accordance with some embodiments.

In some embodiments, the wider upper portion 156A extends into the upper portion of the source/drain features 128N and 128P, and the connecting wall 156W is located at a position lower than the top surface of the topmost nanostructure 108. In some embodiments, the wider lower portion 166B extends into the upper portion of the source/drain features 128N and 128P, and the connecting wall 166W is located at a position higher than the bottom surface of the bottommost nanostructure 108.

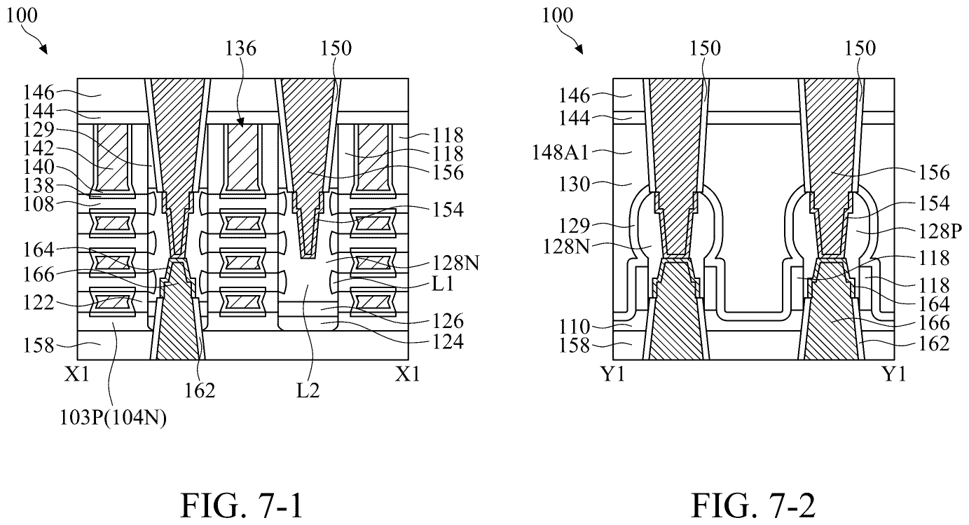

FIGS. 7-1 and 7-2 are cross-sectional views of the semiconductor structure corresponding to lines X1-X1 and Y1-Y1 of FIG. 2, in accordance with some embodiments of the disclosure. The embodiments of FIGS. 7-1 and 7-2 are similar to the embodiments of FIGS. 6B-1 and 6B-2, except that the lower portion of the contact structure 156 has tapered sidewalls, and the upper portion of the contact structure 166 has tapered sidewalls.

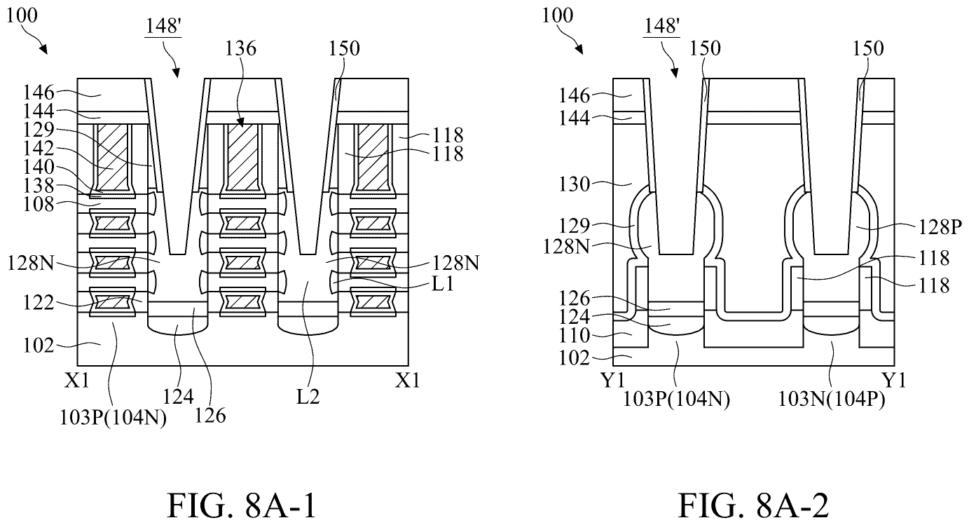

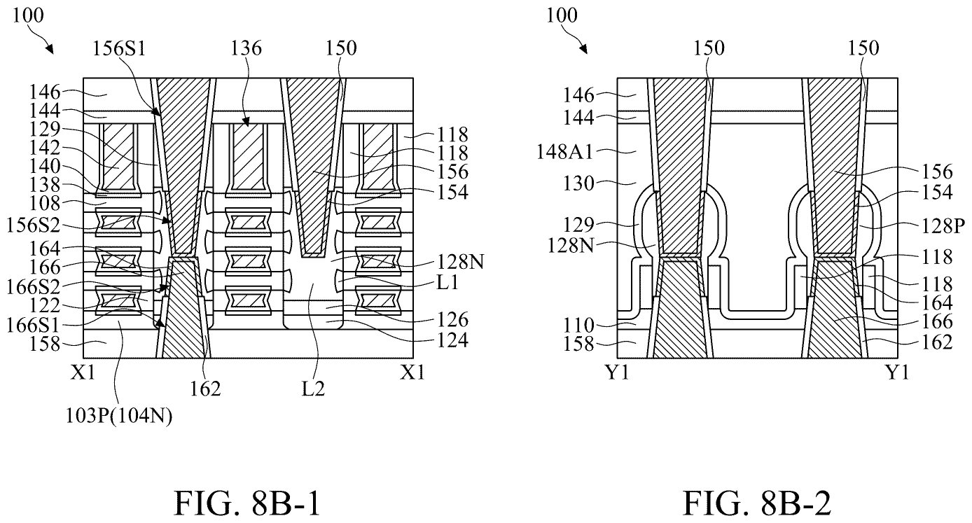

FIGS. 8A-1 through 8B-2 are cross-sectional views illustrating the formation of the semiconductor structure 100 of FIG. 2 at various intermediate stages, in accordance with some embodiments of the disclosure. The figures ending with “−1” correspond to line X1-X1 shown in FIG. 2. The figures ending with “−2” correspond to line Y1-Y1 shown in FIG. 2. The embodiments of FIGS. 8A-1 through 8B-2 are similar to the embodiments of FIGS. 3A-1 to 3N-2, except that the sacrificial layers 152 and 162 are omitted.

Continuing from FIGS. 3F-1 and 3F-2, once the contact liners 150 are formed in the contact opening 148, an etching process is performed on the semiconductor structure 100 to vertically enlarge the contact openings 148, as shown in FIGS. 8A-1 and 8A-2, in accordance with some embodiments. The enlarged contact openings 148 is denoted as 148′. Silicide layers 154 are formed on the exposed surfaces of the source/drain features 128N and 128P, and frontside contact structures 156 are formed in the contact opening 148′ on the silicide layers 154, as shown in FIGS. 8B-1 and 8B-2, in accordance with some embodiments.

Similarity, once the contact liners 162 are formed in the contact opening 160, an e tching process is performed on the semiconductor structure 100 to vertically enlarge the contact openings 160, in accordance with some embodiments. Silicide layers 164 are formed on the exposed surfaces of the source/drain features 128N and 128P, and backside contact structures 166 are formed in the contact opening 160′ on the silicide layers 164, as shown in FIGS. 8B-1 and 8B-2, in accordance with some embodiments.

The contact structure 156 and 166 may not have distinct kinked profiles, in accordance with some embodiments. In some embodiments, the slope of the sidewall 156S1 is substantially equal to the slope of the sidewall 156S2, and the slope of the sidewall 166S1 is substantially equal to the slope of the sidewall 166S2. In some other embodiments, the slope of the sidewall 156S1 is different than the slope of the sidewall 156S2, and the slope of the sidewall 166S1 is different than the slope of the sidewall 166S2.

FIGS. 9-1 and 9-2 are cross-sectional views of the semiconductor structure corresponding to lines X1-X1 and Y1-Y1 of FIG. 2, in accordance with some embodiments of the disclosure. The embodiments of FIGS. 9-1 and 9-2 are similar to the embodiments of FIGS. 3N-1 and 3N-2, except that the etching process for vertically enlarging the contact openings 148 and 160 creates smooth curved surfaces.

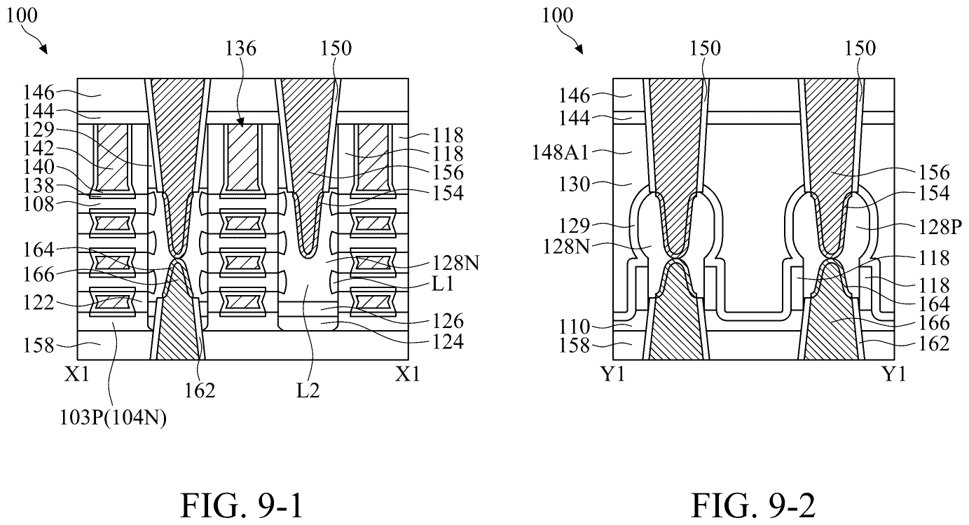

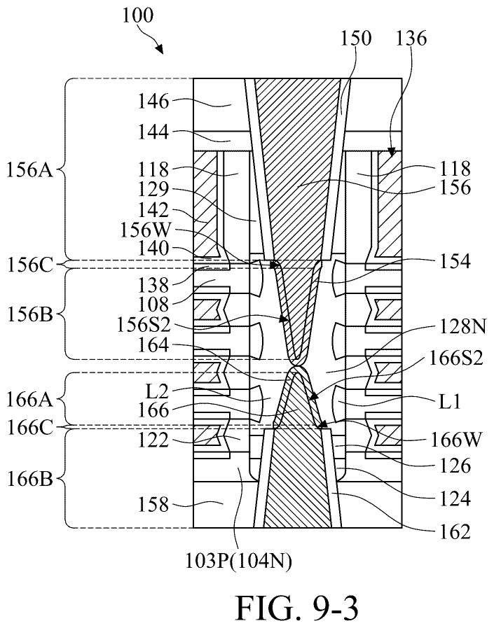

FIG. 9-3 is an enlarged view of FIG. 9-1, in accordance with some embodiments of the disclosure. The frontside contact structure 156 further includes a middle portion 156C between the upper portion 156A and the lower portion 156B, in accordance with some embodiments. The connecting walls 156W of the middle portion 156C and the sidewalls 156S2 of the lower portions 156B are curved. In the direction toward the backside of the semiconductor structure 100, the rate at which the width (e.g., the dimension in the X or Y direction) of the middle portion 156C decreases is greater than the rate at which the width (e.g., the dimension in the X or Y direction) of the upper portion 156A decreases and the rate at which the width (e.g., the dimension in the X or Y direction) of the lower portion 156B decreases.

Similarity, the backside contact structure 166 further includes a middle portion 166C between the upper portion 166A and the lower portion 166B, in accordance with some embodiments. The connecting walls 166W of the middle portion 166C and the sidewalls 166S2 of the upper portions 166A are curved. In the direction toward the frontside of the semiconductor structure 100, the rate at which the width (e.g., the dimension in the X or Y direction) of the middle portion 166C decreases is greater than the rate at which the width (e.g., the dimension in the X or Y direction) of the upper portion 166A decreases and the rate at which the width (e.g., the dimension in the X or Y direction) of the lower portion 166B decreases.

FIGS. 10A-1 through 10C-2 are cross-sectional views illustrating the formation of the semiconductor structure 100 of FIG. 2 at various intermediate stages corresponding to line X1-X1, in accordance with some embodiments of the disclosure. The embodiments of FIGS. 10A-1 through 10C-2 are similar to the embodiments of FIGS. 3A-1 to 3N-2, except that backside contact structures 166 are formed using a self-aligned approach.

After the inner spacer layers 122 are formed, dummy layers 202 are formed in the source/drain recesses 120 on the lower fin elements 103N and 103P, and the second separation layers 126 are formed on the dummy layers 202, as shown in FIGS. 10A-1 and 10A-2, in accordance with some embodiments. In some embodiments, the dummy layers 202 are made of an epitaxial semiconductor material such as silicon germanium or germanium, formed by MBE, MOCVD, or VPE, another suitable technique, or a combination thereof. The dummy layers 202 and the lower fin elements 103N and 103P are made of different materials and have a great difference in etching selectivity. In some embodiments, the separation layer 126 are formed on the dummy layers 202. In some other embodiments, the dummy layers 202 are omitted, and the source/drain features 128N/128P are formed on the dummy layers 202.

The steps described above with respect to FIGS. 3C-1 to 3K-2 are performed, thereby forming the source/drain features 128N and 128P, the contact etching stop layer 129, the first interlayer dielectric layer 130, the final gate stacks 136, the etching stop layer 144, the second interlayer dielectric layer 146, the frontside contact structures 156, and third interlayer dielectric layer 158, as shown in FIGS. 10A-1 and 10A-2, in accordance with some embodiments.

The third interlayer dielectric layer 150 and the underlying lower fin elements 103N and 103P are patterned to form contact openings 160 using a patterned mask layer (now shown) until the dummy layers 202 are exposed, and then an etching process is performed to extend the contact openings 160 into the dummy layers 202 and the second separation layers 126, as shown in FIGS. 10B-1 and 10B-2, in accordance with some embodiments.

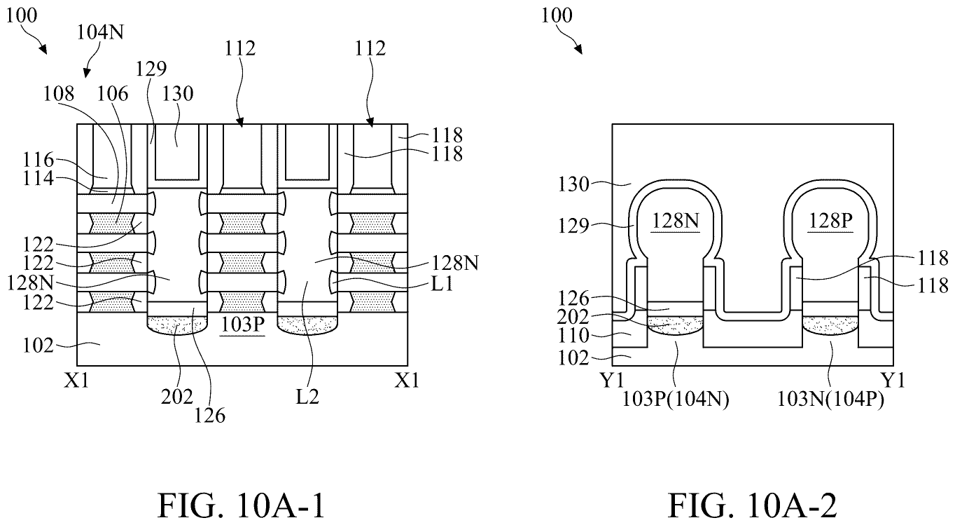

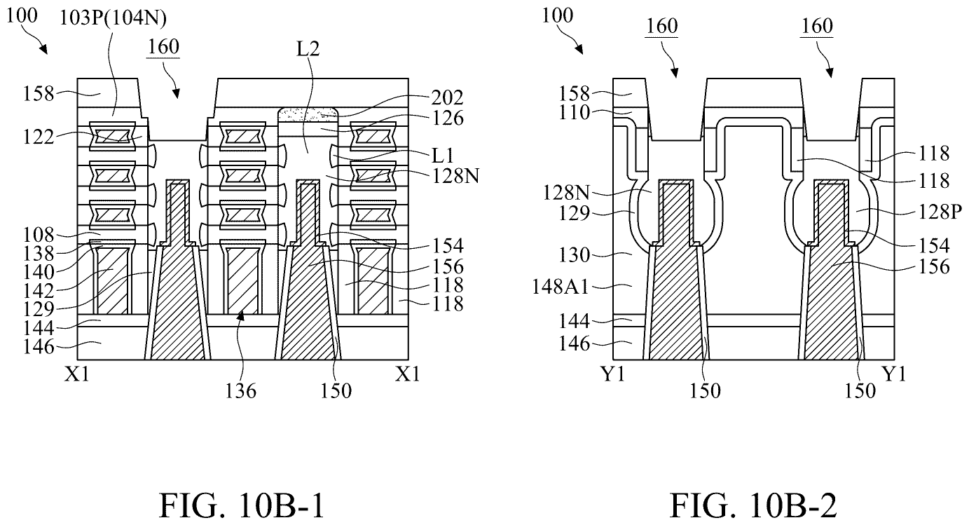

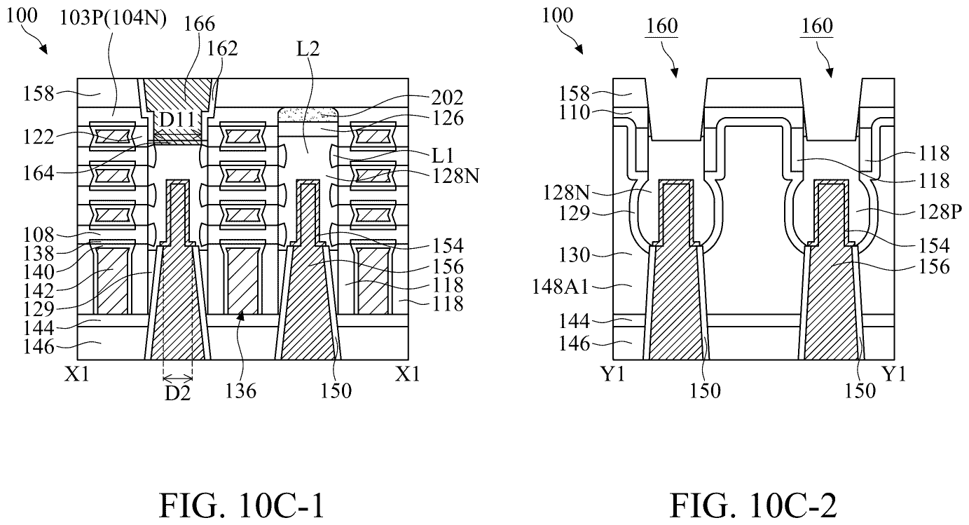

In some embodiments, the dimension of the opening patterns of the patterned mask layer (now shown) in the X direction is greater than the dimension of the underlying dummy layers 202 in the X direction. The enlarged contact openings 160 have a kinked profile, as shown in FIG. 10B-1, in accordance with some embodiments. Because the dummy layers 202 and the lower fin elements 103N and 103P have a great difference in etching selectivity, the lower fin elements 103N and 103P consume little or nothing in the step of the etching process etching the dummy layers 202, in accordance with some embodiments. As a result, the contact openings 160 are formed self-aligned to the dummy layers 202 and underlying the source/drain features 128N and 128P without increasing the risk of leakage between the backside contact structure and the final gate stack.

Contact liners 162 are formed to partially fill the contact openings 160, silicide layers 164 are formed on the exposed surfaces of the source/drain features 128N and 128P, and backside contact structures 166 are formed in the contact opening 160 on the silicide layers 164, as shown in FIGS. 10C-1 and 10C-2, in accordance with some embodiments. Using the self-aligned approach, the backside contact structures 166 may have a greater contact area with the backside power rail, which may reduce the contact resistance of the resulting semiconductor structure. In some embodiments, the dimension D11 of the backside contact structures 166 is greater than the dimension D2 of the frontside contact structure 156 by about 1-10 nm.

FIGS. 11A-1 through 11C-2 are cross-sectional views illustrating the formation of the semiconductor structure 100 of FIG. 2 at various intermediate stages corresponding to line X1-X1, in accordance with some embodiments of the disclosure. The embodiments of FIGS. 11A-1 through 11C-2 are similar to the embodiments of FIGS. 10A-1 through 10C-2, except that backside contact structures 166 are formed using multiple etching processes.

The third interlayer dielectric layer 150 and the underlying lower fin elements 103N and 103P are patterned to form contact openings 160, an etching process is then performed to extend the contact openings 160 into the dummy layers 202 and the second separation layers 126, as shown in FIGS. 11A-1 and 11A-2, in accordance with some embodiments.

Contact liners 162 and sacrificial layers 163 are sequentially formed in the contact openings 160 to partially fill the contact openings 160, and an etching process is performed on the semiconductor structure 100 to vertically enlarge the contact openings 160, as shown in FIGS. 11B-1 and 11B-2, in accordance with some embodiments. The enlarged contact openings 160 is denoted as 160′.

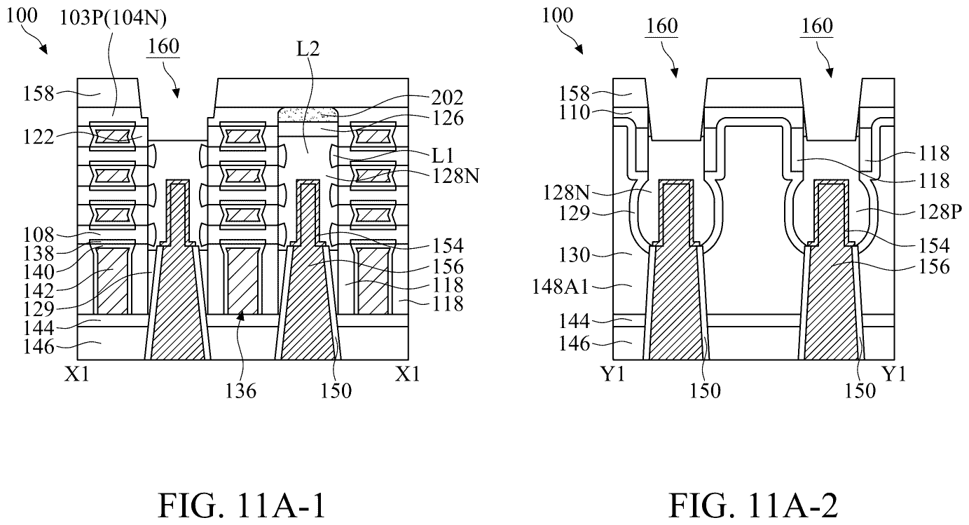

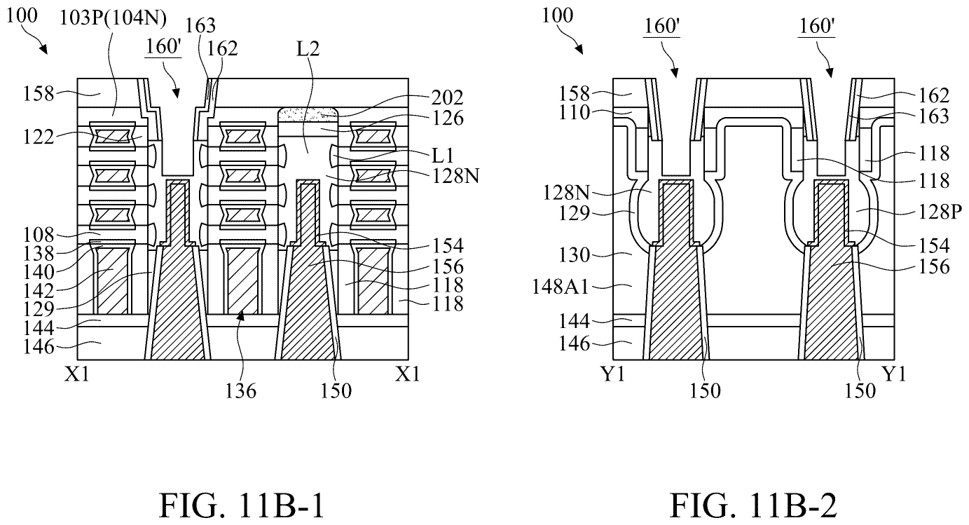

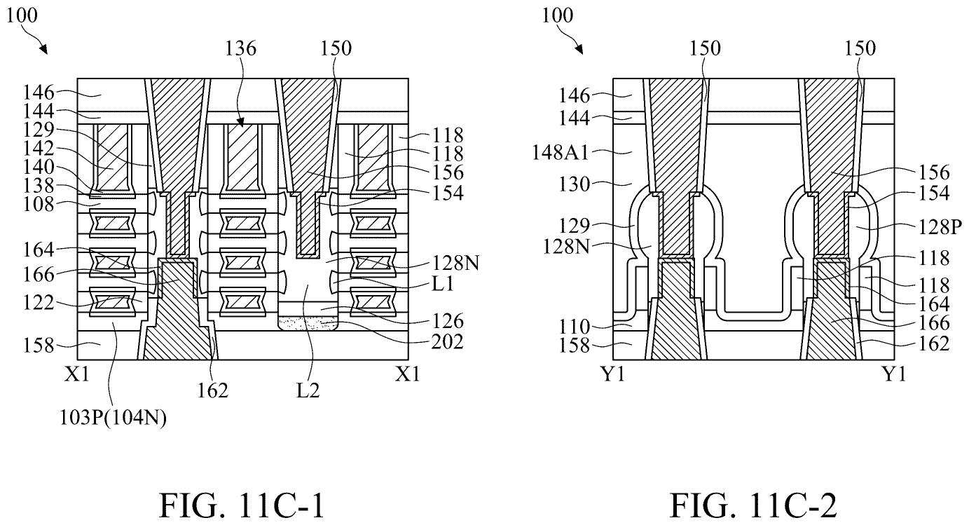

An etching process is performed to remove the sacrificial layer 163, silicide layers 164 are formed on the exposed surfaces of the source/drain features 128N and 128P, and backside contact structures 166 are formed in the contact opening 160′ on the silicide layers 164, as shown in FIGS. 11C-1 and 11C-2, in accordance with some embodiments. The sidewalls of the contact structure 166 may have two kinks, as shown in FIG. 11C-1, in accordance with some embodiments.

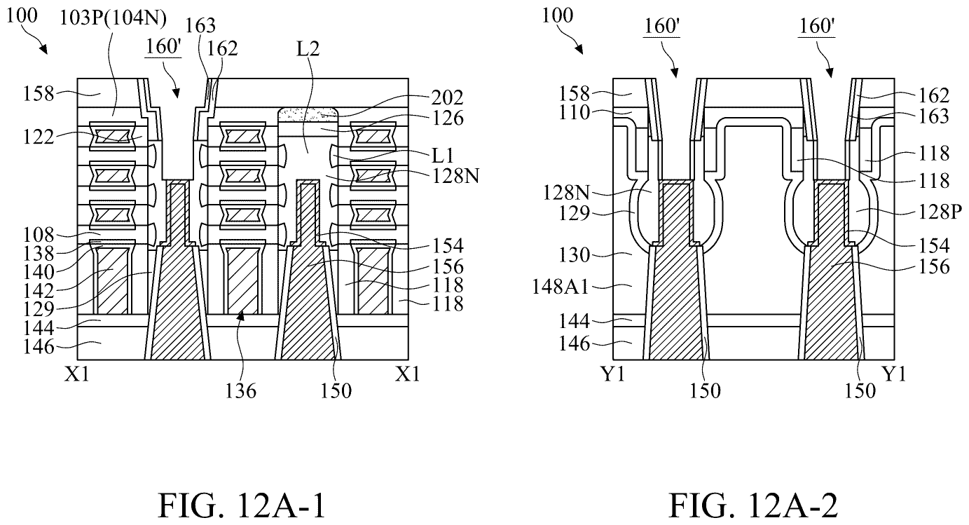

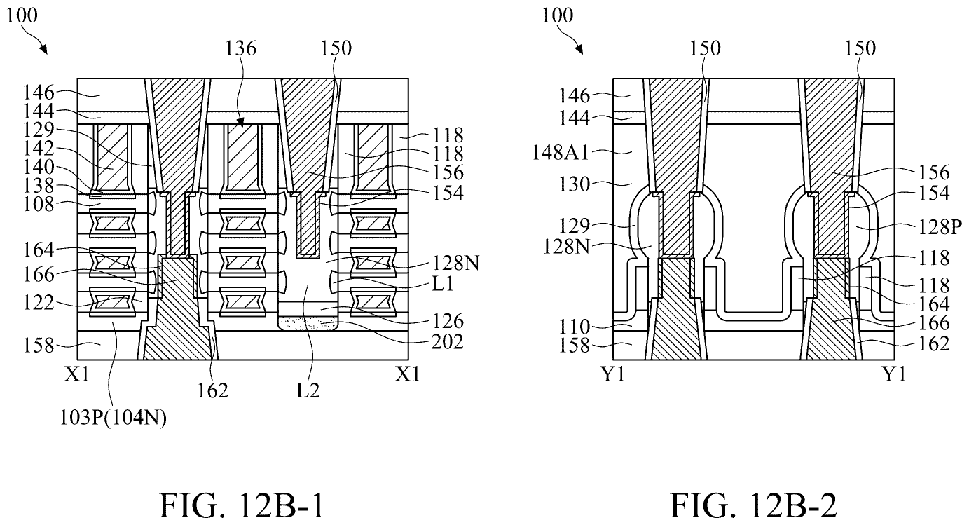

FIGS. 12A-1 through 12B-2 are cross-sectional views illustrating the formation of the semiconductor structure 100 of FIG. 2 at various intermediate stages corresponding to line X1-X1, in accordance with some embodiments of the disclosure. The embodiments of FIGS. 12A-1 through 12B-2 are similar to the embodiments of FIGS. 11A-1 through 11C-2, except that the contact opening 160′ exposes the silicide layer 154.

The contact openings 160′ are formed to expose the silicide layers 154, as shown in FIGS. 12A-1 and 12A-2, in accordance with some embodiments. The backside contact structures 166 are formed in the contact opening 160′ and are in contact with the silicide layers 154, as shown in FIGS. 12B-1 and 12B-2, in accordance with some embodiments.

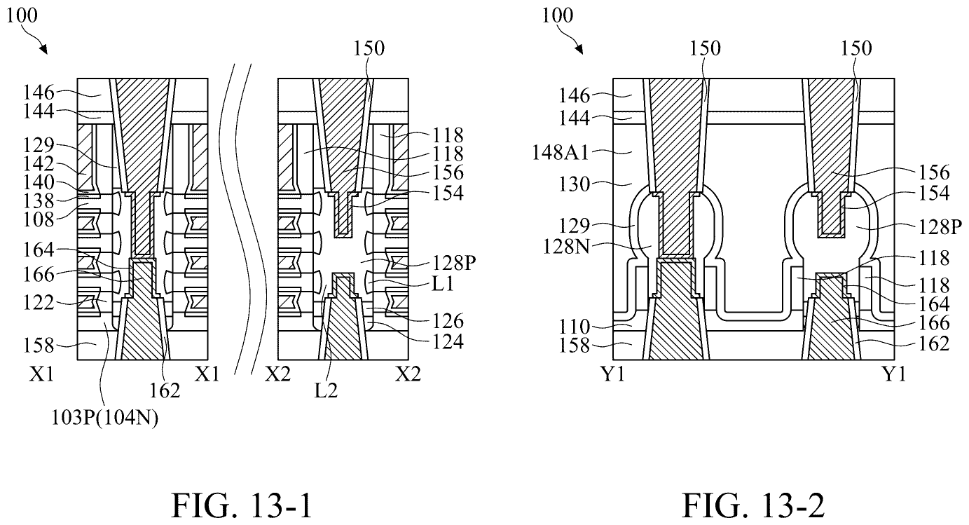

FIGS. 13-1 and 13-2 are a modification of the semiconductor structure 100 of FIGS. 3N-1 and 3N-2, in accordance with some embodiments of the disclosure. FIG. 13-1 correspond to line X1-X1 and line X2-X2 shown in FIG. 2, and FIG. 13-2 correspond to line Y1-Y1 shown in FIG. 2. The embodiments of FIGS. 13-1 and 13-2 are similar to the embodiments of FIGS. 3N-1 and 3N-2, except that the dimensions of the contact structures of the n-channel nanostructure transistors NMOSFET is different than the dimensions of the contact structures of the p-channel nanostructure transistors PMOSFET.

In some embodiments, the performance of the p-channel nanostructure transistor PMOSFET may be boosted by imparting stress and/or strain to the channel regions using the p-type source/drain features 128P. In some embodiments, the contact structures 156 and 166 of the p-channel nanostructure transistor PMOSFET are formed to have a smaller dimension in the X direction than the dimension in the X direction of the contact structures 156 and 166 of the n-channel nanostructure transistor NMOSFET, as shown in FIG. 13-1. In some embodiments, the contact structures 156 and 166 of the p-channel nanostructure transistor PMOSFET are formed to have a smaller dimension in the Y direction than the dimension in the Y direction of the contact structures 156 and 166 of the n-channel nanostructure transistor NMOSFET, as shown in FIG. 13-2.

Due to the characteristics of the etching process, the larger the critical dimension of the contact opening (or opening pattern), the greater the etching amount. In some embodiments, the contact structures 156 and 166 of the p-channel nanostructure are shallower than the contact structures 156 and 166 of the n-channel nanostructure transistor NMOSFET, as shown in FIGS. 13-1 and 13-2. Therefore, the source/drain feature 128P may have more remaining volume than the source/drain feature 128N, thereby boosting the performance of the p-channel nanostructure transistor.

As described above, the aspect of the present disclosure is directed to forming contact structures of a semiconductor structure. In accordance with the embodiments of the present disclosure, the contact openings 148′ are formed using two separate etching processes which are respectively performed before and after the formation of the contact liner 150. As a result, the contact structure 156 may extend to a deep position while preventing the contact structure from coming into contact with the barrier layers of the source/drain feature, or reducing the contact area between the contact structure 156 (or the silicide layer 154) and the barrier layers. In addition, the risk of leakage between the contact structure 156 and the final gate stack 136 may be reduced. Therefore, the performance and/or the reliability of the resulting semiconductor devices may be enhanced, e.g., higher DC performance and/or lower leakage.

Embodiments of a semiconductor structure and the method for forming the same may be provided. The method includes etching the interlayer dielectric layer to form a contact opening exposing the source/drain feature, forming a contact liner along sidewalls of the contact opening, and etching the source/drain feature to vertically extend the contact opening. The contact area between the contact structure (or the silicide layer) and the barrier layers of the source/drain features may be reduced, or avoided. Therefore, the performance of the resulting semiconductor devices may be enhanced.

In some embodiments, a method for forming a semiconductor structure is provided. The method includes forming an active region over a substrate, forming a source/drain feature on the active region, forming a contact etching stop layer to cover the source/drain feature, and forming a first interlayer dielectric layer over the contact etching stop layer. The active region extends lengthwise along a direction. A thickness of the contact etching stop layer along the direction is less than a thickness of the first interlayer dielectric layer, and a dielectric constant of the contact etching stop layer is greater than a dielectric constant of the first interlayer dielectric layer. The method further includes etching the first interlayer dielectric layer to form a first opening exposing the source/drain feature, forming a first contact liner along sidewalls of the first opening, etching the source/drain feature to vertically extend the first opening, thereby forming a first enlarged opening, and forming a first contact structure in the first enlarged opening. The method further includes forming a second contact structure through the source/drain feature from a backside surface of the source/drain feature to the first contact structure.

In some embodiments, a method for forming a semiconductor structure is provided. The method includes forming an epitaxial feature over a source/drain region of an active region. The active region includes a fin element and a plurality of channel layers over the fin element. The epitaxial feature includes first layers interfacing the channel layers and a second layer spaced apart from the channel layers by the first layer. A concentration of the dopant in the first layer varies from a concentration of the dopant in the second layer. The method further includes forming a first interlayer dielectric layer over a frontside surface of the epitaxial feature, forming a first contact structure through the first interlayer dielectric layer and on the frontside surface of the epitaxial feature, forming a second interlayer dielectric layer over a backside surface of the epitaxial feature, forming an opening through the fin element and exposing the backside surface of the source/drain feature, forming a contact liner along sidewalls of the opening, etching the epitaxial feature to extend the opening, and forming a second contact structure in the opening. A bottom surface of the first contact structure is lower than a bottom surface of a topmost one of the channel layers.

In some embodiments, a semiconductor structure is provided. The semiconductor structure includes first nanostructures vertically stacked over each other, and a first source/drain feature adjoining the first nanostructures. A thickness of the first source/drain feature is different from a width of the first source/drain feature in a cross-sectional view. The semiconductor structure further includes a first contact etching stop layer covering the first source/drain feature, a first interlayer dielectric layer on the first contact etching stop layer, and a first contact structure through the first interlayer dielectric layer, the first contact etching stop layer, and the first source/drain feature. The first contact structure includes a first portion through the first dielectric layer and a second portion through the first source/drain feature, a first sidewall of the first portion is connected to a second sidewall of the second portion through a connecting wall, and the second sidewall is indented from the first sidewall by a distance.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming an active region over a substrate, wherein the active region extends lengthwise along a direction;
forming a source/drain feature on the active region;
forming a contact etching stop layer to cover the source/drain feature;
forming a first interlayer dielectric layer over the contact etching stop layer, wherein a thickness of the contact etching stop layer along the direction is less than a thickness of the first interlayer dielectric layer, and a dielectric constant of the contact etching stop layer is greater than a dielectric constant of the first interlayer dielectric layer;
etching the first interlayer dielectric layer to form a first opening exposing the source/drain feature;
forming a first contact liner along sidewalls of the first opening;
etching the source/drain feature to vertically extend the first opening, thereby forming a first enlarged opening;
forming a first contact structure in the first enlarged opening; and
forming a second contact structure through the source/drain feature from a backside surface of the source/drain feature to the first contact structure.

2. The method for forming the semiconductor structure as claimed in claim 1, further comprising:
forming a sacrificial layer on the first contact liner along the sidewalls of the first opening before etching the source/drain feature to extend the first opening; and
removing the sacrificial layer after etching the source/drain feature to extend the first opening.

3. The method for forming the semiconductor structure as claimed in claim 1, further comprising:
thinning down the contact liner after etching the source/drain feature to vertically extend the first opening.

4. The method for forming the semiconductor structure as claimed in claim 1, further comprising:
flipping the substrate upside down;
removing the substrate;
forming a second interlayer dielectric layer over the backside surface of the source/drain feature; and
etching the second interlayer dielectric layer to form a second opening exposing the backside surface of the source/drain feature.

5. The method for forming the semiconductor structure as claimed in claim 4, further comprising:
forming a second contact liner along sidewalls of the second opening; and
etching the source/drain feature to vertically extend the second opening, thereby forming a second enlarged opening, wherein the second contact structure is formed in the second enlarged opening.

6. The method for forming the semiconductor structure as claimed in claim 5, wherein a dimension of the second enlarged opening in the direction is greater than a dimension of the first enlarged opening in the direction.

7. The method for forming the semiconductor structure as claimed in claim 1, further comprising:
forming a stack of alternating first semiconductor layers and second semiconductor layers over the substrate;
patterning the stack into the active region;
removing the first semiconductor layers; and
forming a gate stack across the active region, wherein the gate stack surrounds the second semiconductor layers.

8. The method for forming the semiconductor structure as claimed in claim 7, wherein a topmost one of the second semiconductor layers is a first channel layer, a bottom surface of the first opening is higher than a bottom surface of the first channel layer, and a bottom surface of the first enlarged opening is lower than the bottom surface of the first channel layer.

9. The method for forming the semiconductor structure as claimed in claim 1, further comprising:
laterally etching the source/drain feature before forming the first contact structure in the first enlarged opening.

10. A method for forming a semiconductor structure, comprising:
forming an epitaxial feature over a source/drain region of an active region, wherein the active region comprises a fin element and a plurality of channel layers over the fin element, the epitaxial feature comprises first layers interfacing the channel layers and a second layer spaced apart from the channel layers by the first layer, and a concentration of the dopant in the first layer varies from a concentration of the dopant in the second layer;
forming a first interlayer dielectric layer over a frontside surface of the epitaxial feature;
forming a first contact structure through the first interlayer dielectric layer and on the frontside surface of the epitaxial feature, wherein a bottom surface of the first contact structure is lower than a bottom surface of a topmost one of the channel layers;
forming a second interlayer dielectric layer over a backside surface of the epitaxial feature;
forming an opening through the fin element and exposing the backside surface of the source/drain feature;
forming a contact liner along sidewalls of the opening;
etching the epitaxial feature to extend the opening; and
forming a second contact structure in the opening.

11. The method for forming the semiconductor structure as claimed in claim 10, further comprising:
forming a silicide layer along a surface of the epitaxial feature exposed from the opening, wherein the second contact structure is formed on the silicide layer.

12. The method for forming the semiconductor structure as claimed in claim 10, further comprising:
forming a dummy layer on the fin element, wherein the epitaxial feature is formed on the sacrificial layer, wherein the dummy layer is made of a semiconductor material with a different composition than the fin element.

13. The method for forming the semiconductor structure as claimed in claim 12, wherein the opening is further formed through the sacrificial layer, and a first portion of the opening through the fin element is wider than a second portion of the opening through the dummy layer.

14. The method for forming the semiconductor structure as claimed in claim 10, further comprising:
forming a sacrificial layer on the contact liner in the opening; and
removing the sacrificial layer after etching the epitaxial feature to extend the opening.

15. The method for forming the semiconductor structure as claimed in claim 14, wherein the second contact structure is separate from the first layers of the epitaxial feature by the second layer of the epitaxial feature.

16. A semiconductor structure, comprising:
first nanostructures vertically stacked over each other;
a first source/drain feature adjoining the first nanostructures, wherein a thickness of the first source/drain feature is different from a width of the first source/drain feature in a cross-sectional view;
a first contact etching stop layer covering the first source/drain feature;
a first interlayer dielectric layer on the first contact etching stop layer; and
a first contact structure through the first interlayer dielectric layer, the first contact etching stop layer and the first source/drain feature, wherein:
the first contact structure includes a first portion through the first dielectric layer and a second portion through the first source/drain feature,
a first sidewall of the first portion is connected to a second sidewall of the second portion through a connecting wall, and
the second sidewall is offset from the first sidewall by a distance.

17. The semiconductor structure as claimed in claim 16, wherein in a cross-sectional view, the first sidewall extends in a first direction, the second sidewall extends in a second direction, and the connecting wall extends in a third direction that is not parallel with the first direction or the second direction.

18. The semiconductor structure as claimed in claim 17, wherein the first direction is not parallel to the second direction.

19. The semiconductor structure as claimed in claim 16, wherein:
the first contact structure further includes a third portion between the first portion and the second portion of the first contact structure,
a width of the first portion of the first contact structure decreases downwardly at a first rate,
a width of the second portion of the first contact structure decreases downwardly at a second rate,
a width of the third portion of the first contact structure decreases downwardly at a third rate, and
the third rate is greater than the first rate and the second rate.

20. The semiconductor structure as claimed in claim 16, further comprising:
second nanostructures vertically stacked over each other, wherein the first nanostructures are disposed in a p-type well, and the second nanostructures are disposed in an n-type well;
a second source/drain feature adjoining the second nanostructures, wherein a thickness of the second source/drain feature is different from a width of the second source/drain feature in a cross-sectional view;
a second contact etching stop layer covering the second source/drain feature;
a second interlayer dielectric layer on the second contact etching stop layer; and
a second contact structure through the second interlayer dielectric layer, the second contact etching stop layer and the second source/drain feature, wherein:
the second contact structure is shallower than the first contact structure.
